(19) United States
(12) Patent Application Publication
(10) Pub. No.: US 2015/0255668 A1
(43) Pub. Date: Sep. 10, 2015

(54) THIN FILM INP-BASED SOLAR CELLS USING EPITAXIAL LIFT-OFF

(71) Applicant: Microlink Devices, Inc., (US)

(72) Inventors: Noren Pan, Wilmette, IL (US); Glen Hillier, Spring Grove, IL (US); Mark Wanlass, Golden, CO (US); Christopher Youtsey, Libertyville, IL (US); Jessica Adams, Chicago, IL (US)

(73) Assignee: MICROLINK DEVICES, INC., Niles, IL (US)

(21) Appl. No.: 13/631,533

(22) Filed: Sep. 28, 2012

Related U.S. Application Data
(60) Provisional application No. 61/542,073, filed on Sep. 30, 2011.
(60) Provisional application No. 61/541,945, filed on Sep. 30, 2011.

(51) Int. Cl. H01L 31/18; H01L 31/047; H01L 31/046; H01L 31/0443

(52) U.S. Cl. CPC H01L 31/1896; H01L 31/1844; H01L 31/0443; H01L 31/047; H01L 31/046

(57) ABSTRACT

Methods of producing single-junction or multi-junction InP-based solar cells grown latticed-matched on a InP substrate or grown on metamorphic layers on a GaAs substrate, with the substrate subsequently removed in a nondestructive manner via the epitaxial lift-off (ELO) technique, and devices produced using the methods are described herein.

### RELATED APPLICATIONS

The present application claims benefit of, and priority to, U.S. Provisional Patent Application No. 61/541,945, filed Sep. 30, 2011, and U.S. Provisional Patent Application No. 61/542,073, filed Sep. 30, 2011, each of which is herein incorporated by reference in its entirety.

### STATEMENT OF GOVERNMENT INTEREST

This invention was made with government support from the Air Force Research Laboratory (AFRL) under Contract No. FA9453-09-C-0018, from the National Aeronautics and Space Administration (NASA) under Contract No. NNX09CA40C, and from the Defense Advanced Research Projects Agency (DARPA) under Contract W911NF-09-C-0034 issued by U.S. Army RDECOM ACQ Center. The government has certain rights in this invention.

### BACKGROUND

Multi-junction solar cells are the state-of-the-art photovoltaic technology, having achieved efficiencies greater than 43% under concentrated sunlight. A multi-junction solar cell includes two or more p-n junctions grown sequentially on top of one another with consecutively increasing or decreasing bandgaps. For solar cell applications, in order to increase efficiency it would be desirable to attain subcell bandgaps between 0.67 eV and 1.42 eV. Most multi-junction solar cells in use today are based on Ge or GaAs. However, it is difficult to attain subcell bandgaps between 0.67 eV and 1.42 eV grown on Ge or GaAs without resorting to the use of lattice-mismatched layers, which introduce crystalline defects that degrade cell performance, or nitride-based materials, which often have poor carrier transport and are difficult to grow on an industrial scale.

Although subcell bandgaps in the range 0.67 eV to 1.42 eV can be attained with lattice-matched growth on InP substrates, lattice-matched growth on InP presents many technical challenges and potential disadvantages. For example, InP substrates are substantially more brittle than Ge substrates or GaAs substrates, making processing and handling of InP-based solar cells more difficult, more complex and more costly than processing of GaAs-based solar cells. Further, InP substrates are much more expensive than Ge or GaAs substrates.

### SUMMARY

Example embodiments described herein include, but are not limited to, methods for fabricating thin film InP-based solar cells free of a substrate using epitaxial lift-off, and thin film solar cells produced using epitaxial lift-off.

One embodiment includes a thin film InP-based solar cell free of a substrate. The solar cell includes a window layer, a first subcell, and a thin-film backing layer under tensile stress, with the first subcell between the window layer and the thin-film backing layer.

In some embodiments, the first subcell is lattice-matched to InP. In some embodiments, the first subcell includes at least one of an InGaAs base layer, an InP base layer, or an InGaAsP base layer.

In some embodiments, the solar cell structure is a multi-junction solar cell. In some embodiments the solar cell also includes a second subcell between the first subcell and the backing layer. In some embodiments, the first subcell includes an InP base layer and the second subcell includes an InGaAs base layer. In some embodiments, the first subcell includes an InAlAs base layer, an InAlGaAs base layer, or an InGaAsP base layer, and the second subcell includes at least one of an InAlGaAs base layer, or an InGaAsP base layer. In some embodiments, the first subcell has a bandgap in the range of 1.35 eV-1.45 eV, and the second subcell has a bandgap in the range of 0.6 eV-0.8 eV.

In some embodiments, the solar cell includes a first a first tunnel diode between the first subcell and the second subcell. In some embodiments, the first tunnel diode includes one or both of a heavily-doped GaAsSb layer and a heavily-doped InP layer.

In some embodiments, the solar cell also includes a third subcell between the second subcell and the backing layer. In some embodiments, the first subcell includes an InAlAsSb base layer, the second cell includes at least one of at least one of an InAlGaAs base layer or an InGaAsP base layer, and the third subcell includes at least one of an InGaAs base layer, an InAlGaAs base layer, or an InGaAsP base layer. In some embodiments, the first subcell includes an InAlAs base layer, the second subcell includes at least one of an InAlGaAs base layer or an InGaAsP base layer, and the third subcell includes at least one of an InGaAs base layer, an InAlGaAs base layer or an InGaAsP base layer.

In some embodiments, the solar cell also includes a first tunnel diode between the first subcell and the second subcell, and a second tunnel diode between the second subcell and the third subcell. In some embodiments, the first subcell has a bandgap within a range of 1.46 eV to 2.2 eV, the second subcell has a bandgap within a range of 0.75 eV to 1.5 eV, and the third subcell has a bandgap within a range of 0.6 eV to 0.8 eV. In some embodiments, the first subcell, the second subcell, and the third subcell are lattice-matched to InP.

In some embodiments, the solar cell also includes a fourth subcell between the window layer and the first subcell. In some embodiments a base material of the fourth subcell and a base material of the first subcell is InAlAs or InAlAsSb.

In some embodiments, the window layer includes at least one of an InP layer, an InAlAs layer, or an AlAsSb layer.

Another embodiment includes a method for fabricating an InP-based solar cell free of a substrate. The method includes epitaxially forming a release layer on an InP substrate, epitaxially forming a window layer over the release layer, and epitaxially forming a first subcell over the window layer. The method also includes forming a backing layer over the first subcell, and etching the release layer to separate the solar cell from the InP substrate.

In some embodiments, forming the first subcell over the release layer includes forming a layer lattice-matched to the InP substrate. In some embodiments, forming the first subcell over the release layer includes at least one of forming an InGaAs base layer, forming an InP base layer, forming an InAlGaAs base layer, or forming an InGaAsP base layer.

In some embodiments, the method also includes forming a second subcell over the first subcell, with the backing layer formed over the second subcell. In some embodiments, forming the first subcell includes forming an InP base layer, and forming the second subcell includes forming an InGaAs base layer. In some embodiments, forming the first subcell includes forming at least one of an InAlAs base layer, an InAlGaAs base layer, or an InGaAsP base layer, and forming the second subcell includes forming at least one of an InAlGaAs base layer or an InGaAsP base layer. In some embodiments, the first subcell has a bandgap in the range of 1.35 eV-1.45 eV, and the second subcell has a bandgap in the range of 0.6 eV-0.8 eV.

In some embodiments, the method also includes forming a first tunnel diode between the first subcell and the second subcell. In some embodiments forming a first tunnel diode between the first subcell and the second subcell includes one or both of forming a heavily-doped GaAsSb layer and forming a heavily-doped InP layer.

In some embodiments, the method also includes forming a third subcell over the second subcell with the backing layer formed over the third subcell. In some embodiments, forming the first subcell includes an InAlAsSb base layer, forming the second subcell includes forming at least one of an InAlGaAs base layer or an InGaAsP base layer, and forming the third subcell includes forming at least one of an InGaAs base layer, an InAlGaAs base layer or an InGaAsP base layer. In some embodiments, forming the first subcell includes forming an InAlAs base layer, forming the second subcell includes forming at least one of an InAlGaAs base layer or an InGaAsP base layer, and forming the third subcell includes forming at least one of an InGaAs base layer, an InAlGaAs base layer or an InGaAsP base layer. In some embodiments, the first subcell has a bandgap within a range of 1.46 eV to 2.2 eV, the second subcell has a bandgap within a range of 0.75 eV to 1.5 eV, and the third subcell has a bandgap within a range of 0.6 eV to 0.8 eV.

In some embodiments, the method also includes forming a fourth subcell over the release layer before formation of the first subcell. In some embodiments, a base material of the fourth subcell and a base material of the first subcell is InAlAs or InAlAsSb. In some embodiments, the method also includes forming a first tunnel diode between the first subcell and the second subcell, and forming a second tunnel diode between the second subcell and the third subcell.

In some embodiments, the formed backing layer is under tensile stress during removal of the release layer. In some embodiments, the forming the release layer includes forming at least one of an AlAsSb layer, an AlPSb layer, or a pseudomorphic AlAs layer. In some embodiments, the method further includes forming a window layer over the release layer before forming a base layer of the first subcell.

In some embodiments, the method further includes reusing the InP substrate to fabricate a second InP-based solar cell free of a substrate. In some embodiments, etching the release layer to separate the solar cell from the substrate also separates a plurality of other solar cells from the substrate. In some embodiments, the substrate is a wafer having a diameter within a range of 95 mm to 155 mm.

Another embodiment includes a III-V compound material stack for forming an InP-based solar cell using epitaxial lift-off. The stack includes an InP substrate, a release layer over the InP substrate, a first subcell, and a thin film backing layer with first subcell between the release layer and the backing layer. In some embodiments, the release layer includes an AlAsSb layer, an AlPSb layer and/or a pseudomorphic AlAs layer. In some embodiments, the thin film backing layer is under tensile stress.

Another embodiment includes a method for fabricating an InP-based solar cell free of a substrate on a GaAs substrate. The method includes forming a compositionally-graded plurality of metamorphic buffer layers on a GaAs substrate and epitaxially forming a release layer over the compositionally-graded plurality of metamorphic buffer layers. The method further includes epitaxially forming a window layer over the release layer, and epitaxially forming a first subcell over the window layer. The method also includes forming a backing layer over the first subcell, and etching the release layer to separate the solar cell from the compositionally-graded plurality of metamorphic buffer layers and the GaAs substrate.

In some embodiments, the compositionally-graded plurality of metamorphic buffer layers includes at least fifteen buffer layers. In some embodiments, the compositionally-graded plurality of metamorphic buffer layers includes at least twenty buffer layers.

In some embodiments, forming the first subcell over the release layer includes at least one of forming an InGaAs base layer, forming an InP base layer, forming an InAlGaAs base layer, or forming an InGaAsP base layer.

In some embodiments, the method further includes forming a second subcell over the first subcell with the backing layer formed over the second subcell. In some embodiments, forming the first subcell includes forming an InP base layer, and forming the second subcell includes forming an InGaAs base layer. In some embodiments, forming the first subcell includes forming at least one of an InAlAs base layer, an InAlGaAs base layer, or an InGaAsP base layer, and forming the second subcell includes forming at least one of an InAlGaAs base layer or an InGaAsP base layer. In some embodiments, the method also includes forming a first tunnel diode between the first subcell and the second subcell. In some embodiments, forming the first tunnel diode between the first subcell and the second subcell includes one or both of forming a heavily-doped GaAsSb layer and forming a heavily-doped InP layer.

In some embodiments, forming the release layer includes forming at least one of an AlAsSb layer, an AlPSb layer, or a pseudomorphic AlAs layer. In some embodiments, the formed backing layer is under tensile stress during removal of the release layer. Some embodiments also include forming a window layer over the release layer before forming a base layer of the first subcell. Some embodiments further include reusing the GaAs substrate to fabricate a second InP-based solar cell free of a substrate. In some embodiments, etching the release layer to separate the solar cell from the compositionally-graded plurality of metamorphic buffer layers and the GaAs substrate also separates a plurality of other solar cells from the substrate. In some embodiments, the substrate is a GaAs wafer having a diameter within a range of 95 mm to 155 mm.

Another embodiment includes a III-V compound material stack for forming an InP-based solar cell on a GaAs using epitaxial lift-off. The stack includes a compositionally-graded plurality of metamorphic buffer layers on a GaAs substrate with a top layer of the metamorphic buffer layers having lattice parameters about equal to those of an InP layer. The stack also includes a release layer over the compositionally-graded plurality of metamorphic buffer layers, a first subcell over the release layer, and a thin film backing layer over the first subcell. In some embodiments, the release layer includes at least one of an AlAsSb layer, an AlPSb layer or a pseudomorphic AlAs layer. In some embodiments, the first subcell includes at least one of an InGaAs base layer, an InP base layer, or an InGaAsP base layer.

In some embodiments, the stack also includes a second subcell between the first subcell and the backing layer. In some embodiments, the first subcell includes an InP base layer, and the second subcell includes an InGaAs base layer. In some embodiments, the first subcell includes at least one of an InAlAs base layer, an InAlGaAs base layer, or an InGaAsP base layer, and the second subcell includes at least one of an InAlGaAs base layer, or an InGaAsP base layer. In some embodiments, the stack also includes a first tunnel diode between the first subcell and the second subcell. In some embodiments, the first tunnel diode includes one or both of a heavily-doped GaAsSb layer and a heavily-doped InP layer. In some embodiments, first subcell has a bandgap in the range of 1.35 eV-1.45 eV, and the second subcell has a bandgap in the range of 0.6 eV-0.8 eV. In some embodiments, the window layer includes at least one of an InP layer, an InAlAs layer, or an AlAsSb layer.

The summary above is provided merely to introduce a selection of concepts that are further described below in the detailed description. The summary is not intended to identify key or essential features of the claimed subject matter, nor is it intended to be used as an aid in limiting the scope of the claimed subject matter.

### BRIEF DESCRIPTION OF THE DRAWINGS

The foregoing and other objects, features and advantages of the invention will be apparent from the following description, and from the accompanying drawings, in which like reference characters refer to the same parts throughout the different views. The drawings illustrate principles of the invention and are not to scale (e.g., relative thicknesses of material layers are not to scale).

FIG. 1 schematically depicts a lattice-matched III-V material stack for a single-junction InP-based solar cell, in accordance with an embodiment.

FIG. 2 schematically depicts an ELO single-junction InP-based solar cell formed from a film of layers lifted from material stack of FIG. 1.

FIG. 3 schematically depicts a lattice-matched III-V material stack for a dual-junction InP-based solar cell including a tunnel diode between subcells, in accordance with an embodiment.

FIG. 4 schematically depicts an ELO dual-junction InP-based solar cell formed from a film of layers lifted from the material stack of FIG. 3.

FIG. 5 schematically depicts a lattice-matched III-V material stack for a triple-junction InP-based solar cell including a tunnel diode between each subcell, in accordance with an embodiment.

FIG. 6 schematically depicts an ELO triple-junction InP-based solar cell formed from a film of layers lifted from the material stack of FIG. 5.

FIG. 7 schematically depicts an ELO triple-junction InP-based solar cell including a split top subcell, in accordance with some embodiments.

FIG. 8 is a flow diagram of a method of forming a lattice-matched ELO In—P based solar cell on an InP substrate, in accordance with some embodiments.

FIG. 9 is a flow diagram of a method of forming a lattice-matched ELO multi-junction In—P based solar cell on an InP substrate, in accordance with some embodiments.

FIG. 10 schematically depicts a III-V material stack for forming an ELO InP-based solar cell using metamorphic buffer layers on a GaAs substrate, in accordance with an embodiment.

FIG. 11 is a flow diagram of a method of forming a metamorphic ELO multi-junction In—P based solar cell on a GaAs substrate, in accordance with some embodiments.

FIG. 12 is a graph of I-V operational characteristics for the thin film ELO single-junction InGaAs solar cell and for the conventional non-ELO single-junction InGaAs solar cell on an InP substrate described in Example 1.

FIG. 13 is a graph of quantum efficiency for the thin film ELO single-junction InGaAs solar cell and for the conventional non-ELO single-junction InGaAs solar cell on an InP substrate described in Example 1.

FIG. 14 is a graph of the I-V operational characteristics for the thin film ELO single-junction InP solar cell described in Example 2.

FIG. 15 a graph of I-V operational characteristics for a thin film ELO single-junction InP solar cell and for a conventional non-ELO single-junction InP solar cell on an InP substrate, both with anti-reflection coatings (ARC) as described in Example 2.

FIG. 16 is a graph of I-V operational characteristics for single-junction InP solar cells having different types of window layers as described in Example 2.

FIG. 17 is a graph of quantum efficiency for single-junction InP solar cells having different types of window layers as described in Example 2.

FIG. 18 is a graph of maximum power output of ELO single-junction InP solar cells as a function of exposure to radiation for different types of radiation as described in Example 2.

FIG. 19 is a graph of I-V operational characteristics for the non-ELO 1.0 eV single-junction InGaAsP solar cell as described in Example 3.

FIG. 20 is a graph of quantum efficiency for the non-ELO 1.0 eV single-junction InGaAsP solar cell as described in Example 3.

FIG. 21 is a graph of I-V operational characteristics for the non-ELO 1.2 eV single-junction InGaAsP solar cell as described in Example 3.

FIG. 22 is a graph of quantum efficiency for the non-ELO 1.2 eV single-junction InGaAsP solar cell as described in Example 3.

FIG. 23 is a graph of I-V operational characteristics for a p-on-n tunnel diode and for an n-on-p tunnel diode as described in Example 4.

FIG. 24 is a graph of I-V operational characteristics for a non-ELO dual-junction InP/InGaAs solar cell including a tunnel diode as described in Example 4.

FIG. 25 is a graph of quantum efficiencies of the top cell and for the bottom cell of a non-ELO dual-junction InP/InGaAs solar cell described in Example 4.

FIG. 26 is a graph of optical properties as a function of wavelength for antireflection coatings used on the dual-junction InP/InGaAs solar cell described in Example 4.

FIG. 27 is a schematic diagram of an example ELO triple-junction InAlAsSb/InGaAsP/InGaAs solar cell including quantum wells in the bottom subcell.

FIG. 28 is a schematic diagram of an example split top cell ELO triple-junction InAlAs/InAlAs/InGaAsP/InGaAs solar cell including quantum wells in the bottom subcell.

FIG. 29 is a graph of I-V operational characteristics for metamorphic (MM) ELO InP solar cells grown on GaAs substrates as compared with those for a typical lattice-matched (LM) ELO InP solar cell grown on an InP substrate.

FIG. 30 is a graph of quantum efficiency for the MM ELO InP solar cells grown on GaAs substrates as compared with that of a typical LM ELO InP solar cell grown on an InP substrate.

### DETAILED DESCRIPTION

Embodiments disclosed herein relate to methods of producing single-junction or multi-junction InP-based solar cells grown latticed-matched on a InP substrate or grown on metamorphic layers on a GaAs substrate, with the substrate subsequently removed in a non-destructive manner via the epitaxial lift-off (ELO) technique, and devices produced using the methods.

As explained above, InP-based solar cell devices can employ a different set of lattice-matched III-V materials than used in Ge-based and GaAs-based solar cells. The InP-based lattice-matched II-V materials provide access to 0.67 eV to 1.42 eV bandgap ranges, which enable enhancements in efficiency for solar cells relative to Ge-based and GaAs-based designs. Accordingly, some exemplary ELO InP-based solar cells exhibit higher efficiencies than similar Ge-based and GaAs-based designs.

In some embodiments, the ELO InP-based solar cells are grown latticed-matched on InP substrates. Generally speaking, achievement of high-efficiency solar cells requires high crystalline quality because the absence of defects in a high crystalline quality material reduces the number density of recombination centers at which photo-generated carriers are lost. The best crystalline quality is usually achieved using lattice-matched materials. Lattice-matched InP-based solar cell structures grown epitaxially on InP substrates should have higher crystalline quality, resulting in higher efficiencies, than InP-based solar cells epitaxially grown on metamorphic buffer (lattice-mismatched) layers over GaAs substrates. Furthermore, avoiding lattice-mismatched layers may decrease the growth time, as no metamorphic buffer layer will be required in the structure. Metamorphic buffer layers often include a significant amount of indium, which can increase material costs for buffer layers.

As noted above, InP wafers are much more brittle and fragile than GaAs wafers and Ge wafers substrates, which makes processing and handling during production of non-ELO solar cells on InP wafers much more difficult than processing and handling during production of solar cells on Ge or GaAs wafers. Also, the resulting non-ELO solar cells on InP substrates are much more brittle and fragile than solar cells on Ge or GaAs substrates.

Applicants have addressed the problems of brittle and fragile substrates in resulting InP-based solar cell devices by employing a manufacturing technique, specifically epitaxial lift-off (ELO), which produces lattice-matched InP-based solar cells that do not include an InP substrate. In contrast to conventional non-ELO solar cells on InP substrates, InP-based solar cells fabricated using ELO have much greater mechanical robustness due to the flexibility of the thin films resulting from ELO. The ELO solar cells behave much like thin metal foils. This increased robustness also reduces the cost of solar cells produced using ELO by enabling higher yields during the production process. In addition to being more flexible, ELO InP solar cells are thinner and lighter weight than comparable conventional non-ELO solar cells on InP substrates, which may be particularly advantageous for aviation and space applications. In space applications, the stowed volume of the solar panels usually limits the total power available to the space vehicle. Flexible cells allow the construction of panels that occupy a lower stowed volume, thereby enabling the construction of space vehicles with more available power. Using thin film lightweight solar cells for solar applications may also be desirable because of the weight reductions of the cells due to removal of the substrate.

Further, the manufacturing process for ELO InP-based solar cells allows the InP substrate to be reclaimed (e.g., re-polished) and reused to grow another solar cell. In contrast, some techniques for forming thin film structures free of a substrate involve destroying (e.g., etching) the substrate. Substrate reuse reduces the materials cost of the ELO InP-based solar cells as compared with techniques that damage or destroy the substrate.

Generally speaking, InP-based solar cells have superior tolerance to ionizing radiation than do Ge-based and GaAs-based solar cells. Accordingly, some exemplary ELO InP based solar cells have increased tolerance to radiation and improved end-of-life power in high radiation environments, such as space, as compared with Ge-based and Ga-based solar cells.

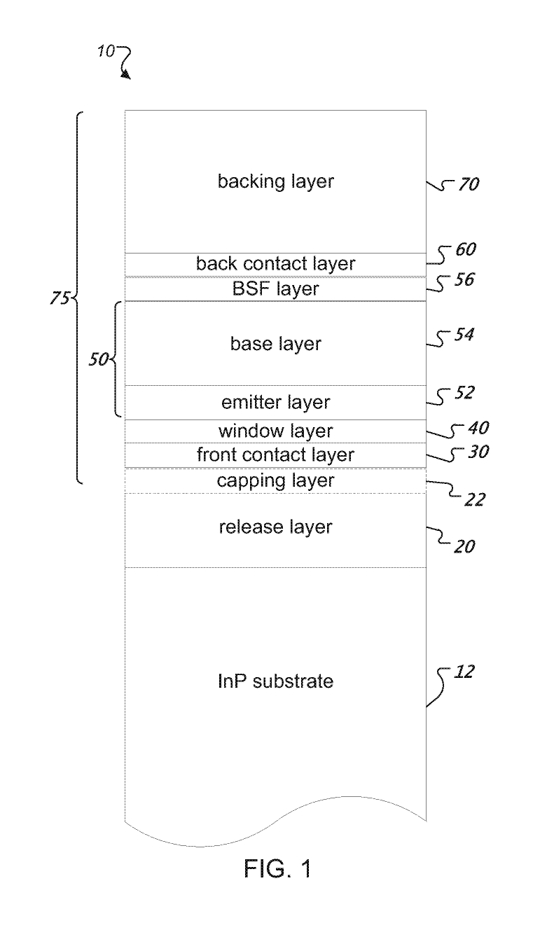

FIG. 1 schematically depicts an exemplary III-V compound material stack 10 for forming a single-junction InP based solar cell using epitaxial lift-off (ELO). The epitaxial stack includes an InP substrate 12, a release layer 20 over the InP substrate, a window layer 40 over the release layer 20, a first subcell 50, and a back contact layer 60 over the first subcell 50. A film backing layer 70 overlays the stack.

As used herein, a reference to a layer over another layer (e.g., a second layer over a first layer) or a layer overlaying another layer can refer to structures in which one layer is directly over or in contact with another layer (e.g., the second layer over and in contact with the first layer), and structures in which one layer is over another layer, but is separated from the layer by one or more intervening layers (e.g., the second layer is over the first layer, but one or more layers are between the first layer and the second layer).

Each subcell in a solar cell includes a base layer and an emitter layer that form a p-n junction with an associated bandgap energy. In some embodiments, the base layer is a p-type layer and the emitter layer is an n-type layer. In other embodiments, the base layer is an n-type layer and the emitter is a p-type layer. In the examples described below, the doping type of each doped layer in a stack may be switched (n to p or p to n) to yield additional example solar cells.

The first subcell 50, which is disposed between the window layer 40 and the back contact layer 60, includes an emitter layer 52. The emitter layer 52 and the base layer 54 form a p-n junction. In some embodiments, a material of the base layer may be the same material as that of an emitter layer, with the base layer and the emitter layer having different dopants. In some embodiments, a material of the base layer may be different than that of the emitter layer.

In some embodiments, the base layer of the first subcell is an InP layer (see Example 2 below). In some embodiments the base layer of the first subcell includes an InGaAs layer (see Example 2 below), or an InGaAsP layer (see Example 3 below). In some embodiments, the first subcell is lattice-matched to InP, which enables high quality crystal layer structure with low defects. In some embodiments, the first subcell has a bandgap falling within a range of 0.6 to 2.2 eV.

In some embodiments, the stack 10 includes a back surface field (BSF) 56 layer in contact with the base layer 54 of the subcell 50. The BSF is a heavily-doped layer that forms a heterojunction with the base layer 54 to reduce electron-hole recombination at a back surface of the base layer 54, thereby increasing efficiency. Similarly, the heavily-doped window layer 40, which is in contact with the emitter layer 52, forms a heterojunction with the emitter layer 52 to reduce electron-hole recombination at a front surface of the emitter layer 52. In some embodiments, the BSF layer is an InP layer (see Examples 1 and 3 below) or an InAlAs layer (see Example 2 below).

As used herein, the front side of the solar cell is the side designed to receive incident photons and the backside of the solar cell is the side facing away from the side designed to receive incident photons. For a non-ELO deposition stack, a top surface of a layer in the stack is the front surface of the layer in the final solar cell and a bottom surface of a layer in the stack is a back surface of the layer in the final solar cell. However, the ELO process involves separating layers above the release layer, which are referred to herein as solar cell layers, from the substrate thereby creating a film of lifted-off layers, and inverting and processing the lifted-off layers to form a solar cell. Because the ELO process involves inversion of the of lifted-off layers, a top surface of a layer in an ELO stack becomes the back surface of the layer in the solar cell, and the bottom surface of a layer in an ELO stack becomes the front surface of the layer in the solar cell.

As shown, the stack further includes a front contact layer 30, which may be referred to as an emitter contact layer, between the release layer 20 and the window layer 40. In some embodiments, the front contact layer 30 is an InGaAs layer (see Examples 1 and 2 below). In some embodiments, the back contact layer is an InGaAs layer (see Examples 1 and 2 below).

The window layer 40 should have a high bandgap relative to that of the first subcell 50. In some embodiments, the window layer includes a highly-doped InP layer (see Example 2 below), a highly-doped InAlAs layer (see Example 1 below), or a highly-doped AlAsSb layer.

The film backing layer 70, which is over the back contact layer 60, is under biaxial tensile stress. In some embodiments, the backing layer 70 is formed on the stack 10. In other embodiments, the backing layer may be applied to or deposited on the stack 10.

The release layer 20 is removed by selective etching to separate the layers above the release layer, which are referred to herein as cell layers 75, from the substrate 12, forming a film of cell layers, which is inverted to form one or more solar cells. In some embodiments, a buffer layer may separate the cell layers 75 from the release layer 20.

During selective etching, the tensile stress in the backing layer 70 exerts a force on the underlying layers that pulls the portion of the cell layers 75 over the etched portion of the release layer 20 away from the substrate 12, aiding in further etching the release layer 20 and separated the cell layers 75 from the substrate 12. Because the stress in the backing layer 70 itself exerts a force on the underlying layers, no external mechanical intervention is needed during etching of the release layer 20, or to separate the cell layers 75 from the substrate 12 during lift-off. For example, there is no need to add weights to the backing layer 40 or the substrate 12 during etching, or to apply Kapton or wax over the substrate or over the backing layer 40 before lift-off.

In some embodiments, the backing layer is a relatively thick, flexible metal layer. For example, in some embodiments, the backing layer may be a 25 μm-50 μm thick metal layer. In some embodiments, a conductive backing layer can be used as a back contact in the resulting solar cell. The term cell layers generally refers to layers in the stack above the release layer that form the “released” or “lifted-off” thin film of layers after etching the release layer, however, a final resulting solar cell may include all of, or only some of, the layers in the film of layers released from the substrate. In some embodiments, one or more of the cell layers may not be incorporated into a resulting ELO solar cell. For example, in some embodiments, the backing layer may be removed from the film of layers during further processing.

In some embodiments, the release layer includes a ternary layer (e.g., an AlAsSb layer or an AlPSb layer). In some embodiments, the release layer includes a pseudomorphic AlAs layer. Applicants faced significant challenges in developing an epitaxial (lattice-matched) release layer for use on an InP substrate. Release layer materials developed for other semiconductor substrates such as Ge and GaAs substrates are not suitable as release materials for InP substrates, at least due to the lattice constant of InP substrates being substantially different than that of Ge substrates and GaAs substrates.

Applicants researched various materials for use as a release layer on InP substrates. Many of the release materials employed by the Applicants include materials that are more challenging to grow and more difficult to characterize than release materials employed for Ge and GaAs substrates. For example, AlAsSb, which was used as a release layer in Examples 1 and 2 below described below, is known to be difficult to grow due to a large miscibility gap that prevents formation of a single phase layer under standard metalorganic chemical vapor deposition (MOCVD) growth conditions. Further, it is difficult to incorporate Sb into materials grown with MOCVD. AlAsSb layers grown using standard MOCVD growth conditions resulted in complex multi-phase structures that were difficult to characterize using X-ray or other standard analysis techniques. During development, the AlAsSb release layer was difficult to characterize optically because it is an indirect bandgap material.

In some embodiments, Applicants addressed the problem of the large miscibility gap and the difficulty in incorporating Sb into the release layer by growing the AlAsSb release layer at a lower temperature than standard MOCVD conditions, i.e., 500° C. to 550° C. Normally, MOCVD for growth of semiconductor layers is not performed at lower temperatures because this can lead to greater incorporation of impurities like carbon and oxygen. However, the greater incorporation of impurities is less relevant for a release layer than it would be for an active device layer incorporated into the resulting device.

Further, Applicants discovered that the high Al compositions in the AlAsSb layer resulted in rapid oxidation of the AlAsSb layer. To address this issue, in embodiments employing AlAsSb in the release layer 20, Applicants grew a capping layer 22 that did not include Al over the release layer 20 to limit degradation of the release layer.

Applicants were not aware of any selective etches for AlAsSb. Applicants employed an HF etch that preferentially etched the release layer and employed an etch stop layer to aid in protecting the emitter contact.

Applicants also encountered similar challenges in developing an AlPSb release layer. Applicants further developed a pseudometamorphic release layer, which did not perform as well as the AlAsSb release layer and the AlPSb release layer.

In some embodiments, a stack includes one or more buffer layers and one or more etch stop layers. In Examples 1 and 2, which are described below, an ELO stack includes a first InP buffer layer between the substrate and the release layer and a second InGaAs buffer layer over the release layer. In Example 1, the ELO stack also includes a first InP etch stop layer under the emitter contact layer, and a second InP etch stop layer over the emitter contact layer.

In some embodiments, the separation of the layers above the release layer 20 from the substrate 12 is performed on a wafer scale, creating a large lifted-off film for producing a plurality of solar cells. After release, the lifted-off film is inverted and processed to produce one or more ELO InP solar cells. The ELO cells in Examples 1 and 2 below were processed by performing wafer scale lift-off on 4-inch InP wafers. However, in other embodiments larger size substrates (e.g., 5-inch, 6-inch wafers, or larger wafers) may be used. The processing to produce a plurality of InP solar cells may include dicing or otherwise separating the large lifted-off multilayer thin film into multiple pieces.

In some embodiments, the InP substrate may be reused for producing another stack to yield another lifted-off film. Exemplary methods for producing ELO solar cells may involve the use of new InP substrates, or fabricating devices on used InP substrates that have been cleaned and polished.

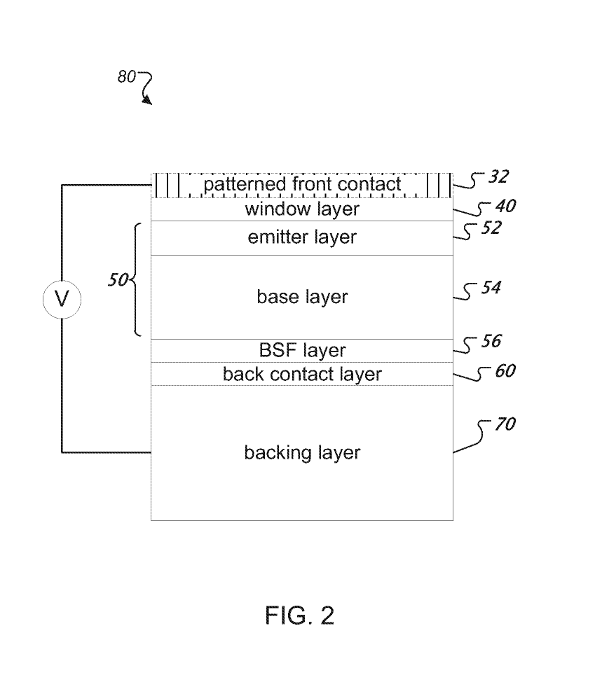

FIG. 2 schematically depicts a resulting single-junction InP solar cell 80 produced from the lifted-off cell layers 75 of the stack 10 in FIG. 1, in accordance with some embodiments. As shown, in some embodiments the backing layer 70 forms the bottom layer of the solar cell. In other embodiments, the backing layer may be removed and the back contact layer may be the bottom layer of the solar cell. The contact layer is patterned to form a patterned emitter 32 contact layer that allows incident photons to reach the underlying window layer 40 over most of the surface of the cell 80.

Incident solar photons that travel through the window 40 are absorbed in the cell. The energy released from the absorption of the photons allows electrons to be promoted to the conduction band, leaving holes in the valence band. The resulting electrons and holes travel by means of thermal diffusion, electric drift and tunneling to respective contacts on the front (emitter/front contact layer 32) and back (back contact layer 60) of the cell establishing a voltage difference between the front of the cell (i.e., the window side) and the back of the cell. Charge carriers extracted at the contacts can be used to power an external load.

Exemplary ELO InP-based solar cells may be single-junction, and/or may include multiple junctions (one, two, three, four, etc.). Some embodiments disclosed herein relate to lattice-matched multi-junction solar cell devices, grown with the subcells in order of increasing or decreasing bandgap on an InP substrate, with the substrate subsequently removed in a non-destructive manner via the epitaxial lift-off (ELO) technique.

Most lattice-matched multi-junction solar cells are presently grown on GaAs or Ge substrates, due partly to the high cost of the InP substrate. Multi-junction solar cells grown on InP substrates are preferable to those grown on GaAs in many cases because lattice-matched InP-based III-V materials have a wider range of bandgaps than can be attained using lattice-matched GaAs-based materials for the subcells. This allows better matching of the subcell bandgaps to the solar spectrum without resorting to lower quality lattice-mismatched growth, such as for inverted metamorphic (IMM) structures. Further, multi-junction solar cells lattice-matched to InP have a favorable combination of subcell bandgaps that are predicted to give a higher power conversion efficiency than current state-of-the-art multi-junction cells, which are usually lattice-matched to GaAs or Ge.

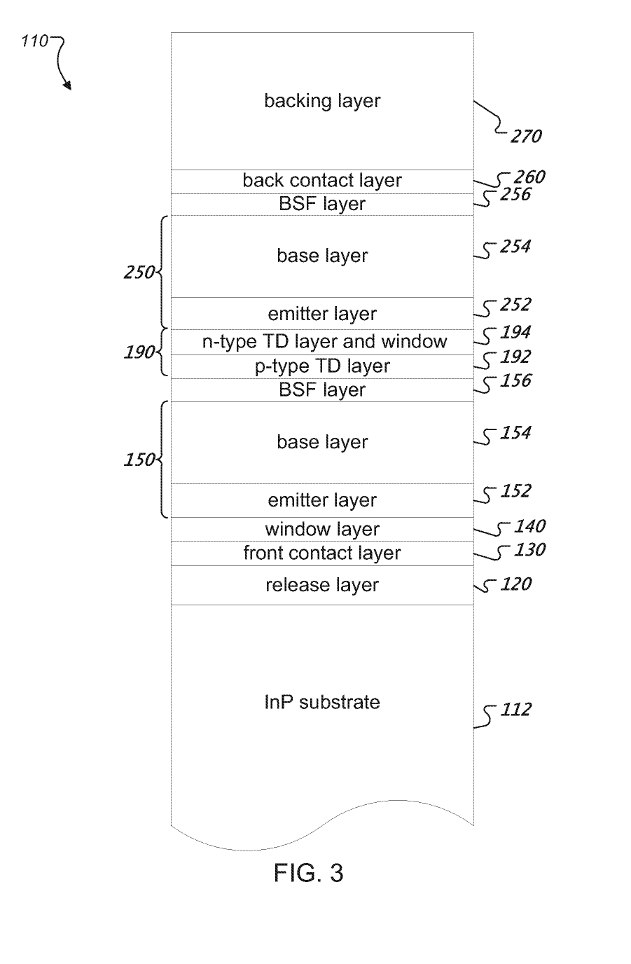

For example, FIG. 3 illustrates a stack for an exemplary dual-junction InP-based solar cell. As shown in FIG. 3, the stack includes an InP substrate 112 with a release layer 120 over the substrate. An emitter contact layer 130, a window layer 140, and a first subcell 150, which includes an emitter layer 152 and a base layer 154, are formed over the release layer 120. Additionally, a BSF layer 156 is formed over the base layer 154

The stack 110 also includes a second subcell 250, which includes a base layer 254 and an emitter layer 252. A second BSF layer 256 and a back contact layer 260 are formed over the base layer 254. A backing layer 270 is formed over, deposited on, or applied over the stack.

As shown, the first subcell 150 is separated from the second subcell 250 by a tunnel diode 190, in accordance with some embodiments. The tunnel diode 190 includes a p-type layer 192 and an n-type layer 194. The tunnel diode 190 provides electrical contact between the base 154 of the first subcell and the emitter 252 of the second subcell without shifting of energy bands or resistive losses. The n-type tunnel diode layer 194 also functions as a window layer for the second subcell 250. The tunnel diode may alternatively be described as a tunnel junction between the first subcell and the second subcell.

In some embodiments, the tunnel diode 190 includes one or more layers of heavily-doped GaAsSb or heavily-doped InP (see Example 3 below). Applicants faced significant challenges in developing an epitaxial InP lattice-matched tunnel diode. The tunnel diode must be highly doped to produce degenerate layers with a sufficiently high bandgap to avoid absorbing optical photons that could be absorbed by the second subcell. It is relatively easy to achieve highly-doped p-type GaAs materials using high levels of carbon doping due to the low diffusivity of carbon in GaAs. In contrast, Zinc, which is used for p-type doping in InP, has a relatively high diffusivity in InP, meaning that the Zinc tends to diffuse out of the highly-doped diode layer into neighboring layers. In some embodiments, Applicants employed a highly p-doped GaAsSb layer (doped with C) and a highly n-doped InP layer (doped with Te) for the tunnel diode (see Example 4 below). The level of doping in the layers should be sufficient to achieve degeneracy in the layers. In some embodiments, the tunnel diode may include an InAlAsSb layer, an InAlAs layer, an InAlAs layer and/or an InP layer. In some embodiments the tunnel diode may include an AlAsSb layer, however this material is more likely to be degraded during etching of the release layer.

Release layer materials described herein with respect to the ELO single-junction InP-based solar cell are also suitable for ELO multi-junction InP-based solar cells. Likewise, window materials, buffer layer materials, etch stop materials, etc. described herein with respect to ELO single-junction InP-based solar cells are also suitable for ELO multi-junction InP-based solar cells.

In some embodiments, the first subcell 150 is lattice-matched to InP and the second subcell 250 is lattice-matched to InP. In some embodiments, all layers between BSF layer 556 and window layer 340 are lattice-matched to InP.

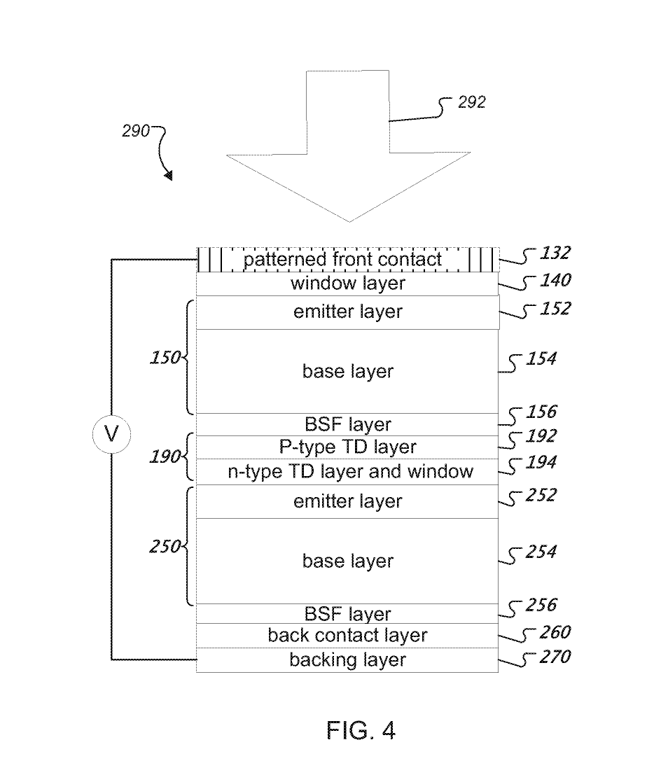

FIG. 4 schematically depicts the resulting ELO dual-junction InP-based solar cell 290 after the lifted-off layers are inverted and processed. As shown, the first subcell 150 is the top subcell and the second subcell 250 is the bottom subcell (e.g., further from the window 140). The front contact layer 132 is patterned to allow most of the light 292 incident on the top of the cell to reach the window layer 140. In the first subcell 250 a portion of the light is absorbed and converted to current. In general, the top cell (first subcell 150) will have a high bandgap, such that higher energy light (higher frequency light) is absorbed in the first subcell allowing light with less energy (lower frequency light) to pass through the first subcell and on lower subcells with lower bandgaps (e.g., second subcell 250). In general, the bandgap of the second subcell 250 will be lower such that some of the low-energy light that passed through the first subcell 150 will be absorbed in the second subcell 250. For example, in some embodiments, the first subcell has a bandgap in the range of 1.35 eV-1.45 eV and the second subcell has a bandgap in the range of 0.6 eV-0.8 eV. The dual-junction design enables higher efficiencies than single-junction designs.

In some embodiments, the first subcell may include an InP layer and second subcell may include an InGaAs layer (see Example 4 below). In some embodiments, the first subcell may include an InAlAs layer, an InAlGaAs layer and/or an InGaAsP layer, and the second subcell may include an InAlGaAs layer and/or an InGaAsP layer.

In general, the highest power conversion efficiency is achieved in a multi-junction solar cell when the subcells are configured such that equal numbers of photons are absorbed in each of the subcells. The photocurrent in each subcell should be matched because excess current in any subcell will be lost by absorption of electrons between subcells. Thicknesses of layers in each subcell may be adjusted to help achieve current matching.

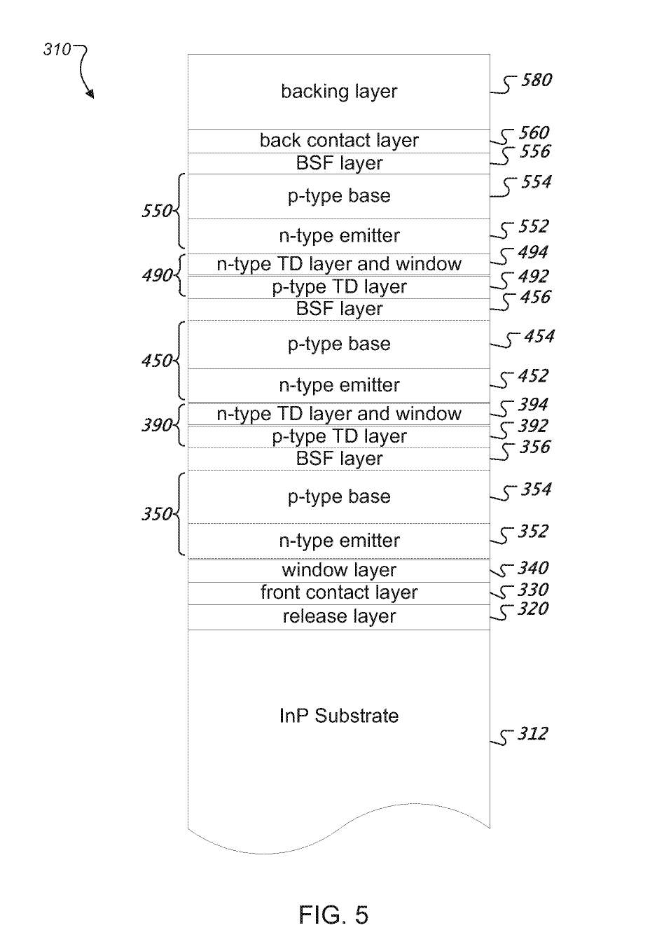

In some embodiments, a lattice-matched ELO InP-based solar cell may include more than two junctions. For example, some embodiments may include a solar cell with a top subcell having a relatively high bandgap, a bottom subcell having a relatively low bandgap, and one or more middle cells having bandgaps falling between that of the top subcell and the that of the bottom subcell. For example, FIG. 5 graphically depicts an embodiment of a stack 310 for forming an ELO triple-junction InP-based solar cell. The stack includes an InP substrate 312 with a release layer 320 over the substrate. An front contact layer 330, a window layer 340, and a first subcell 350, which includes an emitter layer 352 and a base layer 354, are formed over the release layer 320. Additionally, a BSF layer 356 is formed over the base layer 354 of the first subcell.

The stack 310 also includes a second subcell 450, which has a base layer 454 and an emitter layer 452. A second BSF layer 556 overlays the second subcell 550. As shown, the first subcell 350 may be separated from the second subcell 450 by a tunnel diode 390, in accordance with some embodiments. The tunnel diode 390 includes a p-type layer 392 and an n-type layer 394. The tunnel diode 390 provides electrical contact between the base 354 of the first subcell and the emitter 452. The n-type tunnel diode layer 394 also functions as a window layer for the second subcell 450.

The stack 310 also includes a third subcell 550, which has a base layer 554 and an emitter layer 552. A third BSF layer 556 overlays the third subcell 550. As shown, the second subcell 450 may be separated from the third subcell 550 by a second tunnel diode 490, in accordance with some embodiments. The second tunnel diode 490 includes a p-type layer 492 and an n-type layer 494. The tunnel diode 490 provides electrical contact between the base 454 of the second subcell and the emitter 552 of the third subcell. The n-type tunnel diode layer 494 also functions as a window layer for the third subcell 450.

The third subcell also includes a third BSF layer 556. A back contact layer 560 for the solar cell is formed over the BSF layer. A backing layer 580 is formed over, or deposited on, the stack 310.

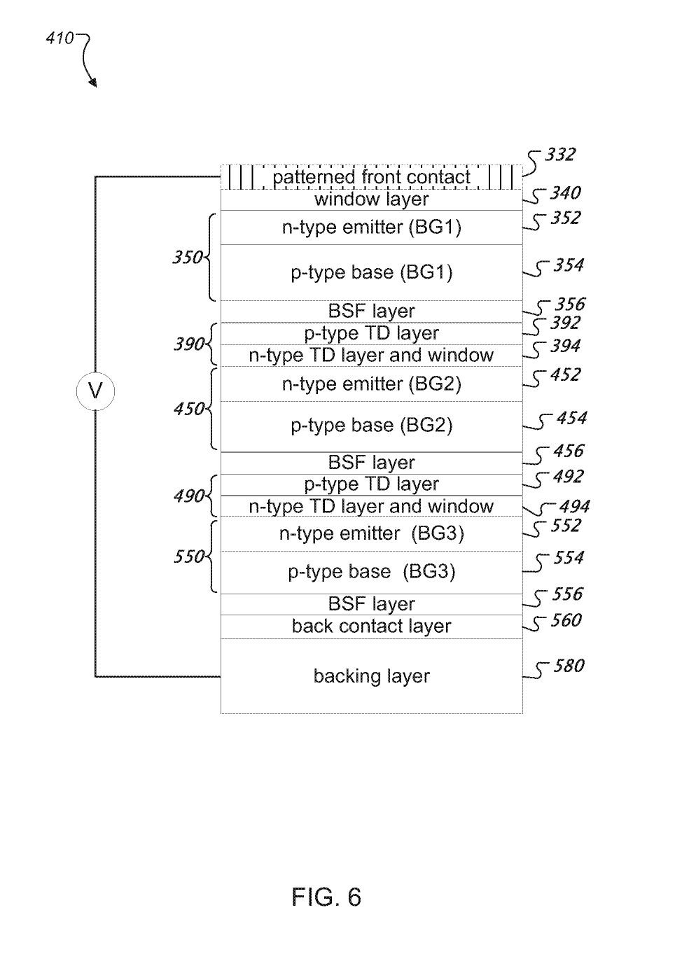

FIG. 6 shows a triple-junction solar cell 410 produced by inverting and processing after etching of the release layer. The front contact layer 332 has been patterned to allow incident photons to reach the window 340 over most of the top surface of the solar cell. After inversion, the first subcell 350 is the top subcell, the second subcell 450 is the middle subcell and the third subcell 550 is the bottom subcell. In some embodiments, the top subcell may have a relatively high bandgap (e.g., BG1 in a range of 1.46 eV to 2.2 eV), the middle subcell may have a mid-level bandgap (e.g., BG2 in a range of 0.75 eV to 1.5 eV) and the bottom subcell may have a relatively low bandgap (e.g., BG3 in a range of 0.6 eV to 0.8 eV).

In some embodiments, the bandgap of the first tunnel diode between the first subcell and the second subcell may be as low as the bandgap of the first subcell. In some embodiments, the bandgap of the second tunnel diode between the second subcell and the third subcell may be as low as the bandgap of the second subcell.

As noted above, each subcell includes a base layer and an emitter layer that form a p-n junction. In some embodiments, the base layer and the emitter layer are the same material with different dopants. In some embodiments, the base layer and the emitter layer are different materials. In some embodiments, the first subcell includes a quaternary alloy as a base layer and/or as an emitter layer. For example, in some embodiments, the first subcell includes an InAlAsSb layer (e.g., an nAlAsSb base layer and/or an InAlAsSb emitter layer), the second subcell includes an InAlGaAs layer and/or an InGaAsP layer, and the third subcell includes an InAlGaAs base layer and/or an InGaAsP layer (see Example 5 below). In some embodiments, the first subcell includes a ternary alloy (e.g., an InAlAs layer), the second subcell includes an InAlGaAs layer and/or an InGaAsP layer, and the third subcell includes an InAlGaAs layer and/or an InGaAsP layer.

In some embodiments, the first tunnel diode between the first subcell and the second subcell includes an InAlAsSb layer, an InAlAs layer, an InAlAs and/or an InP layer. In some embodiments the first tunnel diode may include an AlAsSb layer, however this material is more likely to be degraded during etching of the release layer. In some embodiments, the second tunnel diode between the second subcell and the third subcell may include any of the materials mentioned above with respect to the first diode, and/or may include an InGaAsP layer or an InAlGaAs layer.

In some embodiments, nanostructures, such as strain-balanced quantum well layers, superlattice layers or quantum dots, may be incorporated into the multi-junction solar cell. These structures may further improve the absorption and conversion efficiency of the incident solar spectrum. For example, the bandgap of the bottom subcell can be extended to lower energies while maintaining lattice-matching via the inclusion of strain-balanced quantum well layers or by the incorporation of a superlattice in the bottom subcell. Examples 5 and 6 below include structures employing quantum well layers in bottom subcells.

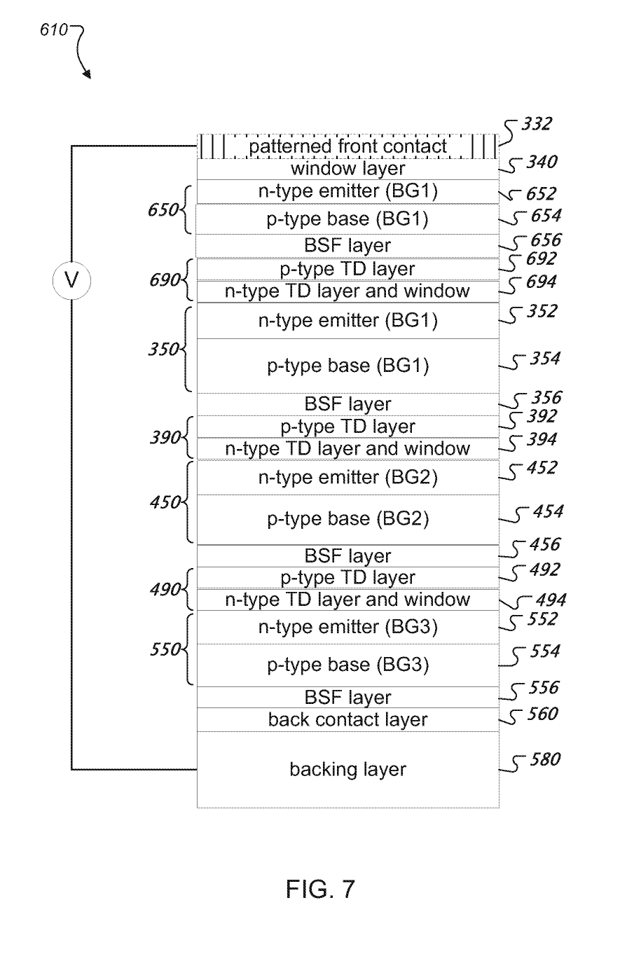

Some embodiments may include a “split cell” meaning that two different subcells have the same bandgap. For example, FIG. 7 includes an ELO triple-junction (TJ) solar cell 610 having four subcells, with the top two subcells having the same bandgap. Although there are four subcells, each including a p-n junction, the solar cell is still referred to as a triple-junction solar cell because there are only three different bandgaps in the subcells. In solar cell 610, an additional top subcell (forth subcell 650), overlays the first subcell 350. The fourth subcell 650, which includes emitter layer 652 and base layer 654 has a bandgap BG1 that is the same as the bandgap of the first subcell BG1. The fourth subcell 650 is separated from the first subcell 350 by a third tunnel diode 690. In the “split cell” the upper subcell of the split cell (fourth subcell 650) is generally thinner than the lower subcell of the split cell (first subcell 350), such that half of the incident photons with an energy greater than BG1 are absorbed in the upper subcell and the rest of the incident photons with an energy greater than BG1 are absorbed in the lower subcell to achieve current matching between the subcells. The extra subcell increases the open circuit voltage of the solar cell, but results in some reduction in short-circuit current. Employing an additional subcell over the first subcell can increase the overall efficiency of a multi-junction solar cell.

In some embodiments the additional top subcell and the first subcell may both include at least one InAlAs layer, the second subcell may include an InAlGaAs layer and/or and InGaAsP layer, and the third subcell may include an InGaAs layer, an InAlGaAs layer and/or an InGaAsP layer (see Example 7 below). In some embodiments, a tunnel diode between the top InAlAs subcells may include InAlAsSb, AlAsSb, InAlAs and InP.

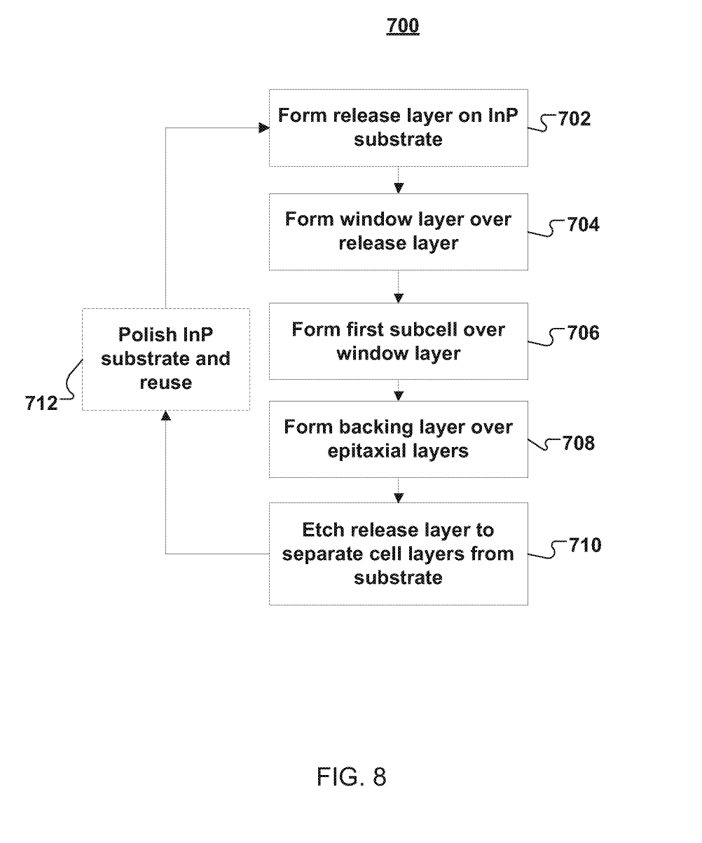

FIG. 8 schematically depicts a method 700 of making a lattice-matched ELO InP based solar cell free of a substrate. For illustrative purposes, the method is described with respect to reference numbers for stack 10 and solar cell 90 depicted in FIGS. 1 and 2. Nevertheless, one of ordinary skill in the art will appreciate that the method may be used to make many different embodiments of InP-based based solar cells. A release layer 20 is epitaxially formed on an InP substrate 12 (step 702). As described above, the release layer 20 may be any material that can be epitaxially formed on an InP substrate and preferentially etched with respect to other overlying layers. In some embodiments, epitaxially forming the release layer 20 includes forming an AlAsSb layer, an AlPSb layer, and/or a pseudomorphic AlAs layer. In some embodiments, a first buffer layer is epitaxially formed over the InP substrate 12 before formation of the release layer 20. In some embodiments, a second buffer layer is epitaxially formed over the release layer 20.

A window layer 40 is epitaxially formed over the release layer 20 (step 704). A front contact layer 30 may be formed over the release layer 20 before forming the window layer 40. In some embodiments, an etch stop layer may be formed before formation of the front contact layer 30. In some embodiments, an etch stop layer may be formed over the front contact layer 30 before formation of the window layer 40.

A first subcell 50 is epitaxially formed over the window layer 40 (step 706). In some embodiments a BSF layer 56 is formed over the first subcell 50. In some embodiments, a back contact layer 60 is formed over the BSF layer 56.

A backing layer 70 is formed over the first subcell 50 and other underling layers (step 708). The layers under the backing layer 70 may be formed using any suitable epitaxial growth technique. For example the layers may be grown using metal organic chemical vapor deposition (MOCVD) expitaxy, using molecular beam epitaxy (MBE), or by using liquid phase epitaxy (LPE). As noted above, when AlAsSb is employed in a release layer, MOCVD epitaxy should be performed at reduced temperatures, relative to conventional MOCVD temperatures, to address problems with formation of multiple phases and complex structures.

In some embodiments, the backing layer 70 may be a relatively thick metal layer, or a relatively thick layer including multiple different metal layers. For example, the backing layer 70 may include a gold layer, a copper layer, a nickel layer, or any combination of the aforementioned. In some embodiments, the backing layer may have a thickness of 5 μm to 50 μm. The backing layer may be produced using a variety of techniques, (e.g., evaporation, plating, or sputtering).

The release layer 20 is selectively etched to separate the solar cell (e.g., cell layers 75) from the InP substrate 12 (step 710). During the release process, the tensile stress in the backing layer 70 exerts a force on the underlying layers that aids in the etching of the release layer 20 and cell layers 75 from the substrate 12, thereby forming a lifted-off film for the solar cell. While the release layer 20 is being etched from the edges of the stack inward, the backing layer 70, which is under tensile stress, exerts a force that pulls the layers above the etched edge portion further away from the underlying substrate 12, promoting access for the etchant to the un-etched portion of the release layer 20. As explained above, because the stress in the backing layer 70 itself exerts a force on the underlying layers, no additional external force is needed on the backing layer 40 to separate the cell layers 75 from the substrate 12 during etching. In some embodiments, the release layer 20 is etched using an acid (e.g., HF). In some embodiments, the InP substrate 12 may be polished and reused to form another ELO InP-based solar cell (step 712).

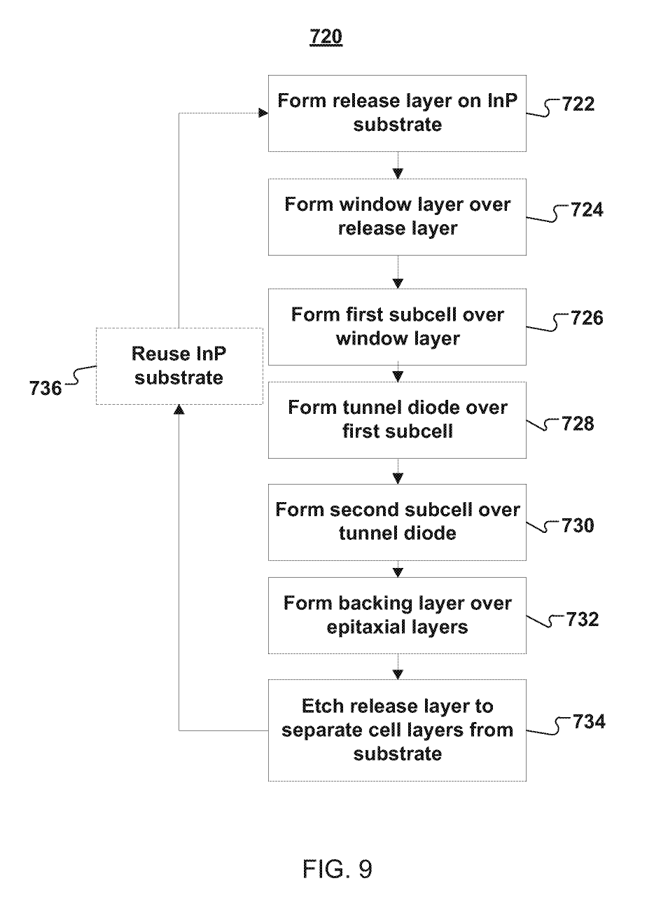

FIG. 9 schematically depicts a method 720 of making a lattice-matched ELO multi-junction InP-based solar cell free of a substrate. For illustrative purposes, the method is described with respect to reference numbers for stack 110 and solar cell 290 depicted in FIGS. 3 and 4. Nevertheless, one of ordinary skill in the art will appreciate that the method may be used to make many different embodiments of InP-based based solar cells. A release layer 220 is epitaxially formed on an InP substrate 112 (step 722). In some embodiments, a first buffer layer is epitaxially formed over the InP substrate 112 before formation of the release layer 120. In some embodiments, a second buffer layer is epitaxially formed over the release layer 120.

A window layer 140 is epitaxially formed over the release layer 20 (step 724). A front contact layer 130 may be formed over the release layer 120 before forming the window layer 140. In some embodiments, an etch stop layer may be formed before formation of the front contact layer 130. In some embodiments, an etch stop layer may be formed over the front contact layer 130 before formation of the window layer 140.

A first subcell 150 is epitaxially formed over the window layer 140 (step 726). A tunnel diode 190 is epitaxially formed over the first subcell 156 (step 728). In some embodiments a BSF layer 156 is formed over the first subcell 150 before formation of the tunnel diode 190. A second subcell 250 is epitaxially formed over the tunnel diode 190 (step 730). In some embodiments, a BSF layer 256 may be formed over the second subcell 250.

A backing layer 270 is formed over the second subcell 250 and other underlying layers (step 732).

The release layer 120 is selectively etched to separate the solar cell layers from the InP substrate 112 (step 734). In some embodiments, the InP substrate is reused to form another InP-based solar cell (step 736).

The ELO technology taught herein is especially well suited for wafer sized lift-off solar cells latticed-matched to an InP substrate. That is, a complete four-inch wafer, six-inch wafer, or larger wafer can be lifted from an InP substrate and result in multi-junction solar cells yields of greater than 85%.

As noted above, generally speaking, lattice-matched growth on InP substrates will result in higher crystalline quality solar cells than non-lattice-matched epitaxial growth, which generally results in more efficient solar cells. However, InP-based solar cells can be grown on GaAs substrates using metamorphic layers that gradually change the lattice constants in the layers from those of the underlying GaAs substrate to those of InP. Abrupt changes in lattice constants create defects due to lattice-mismatch that impair the crystalline quality of subsequent layers, however, gradual changes in the lattice constants reduce the number of lattice-mismatch defects incorporated into the subsequent layers and improve efficiency of devices. Low-energy bandgaps can be obtained by growing metamorphic (MM) solar cells on InP substrates. This allows increased design flexibility, which can result in more efficient solar cell and thermophotovoltaic designs. The disadvantage is that the MM solar cell structure will contain buffer layers and will have worse crystalline quality. In some circumstances the benefits of using GaAs substrates outweigh the disadvantages in reduced quality of the crystalline layers and the resulting reduction in efficiency.

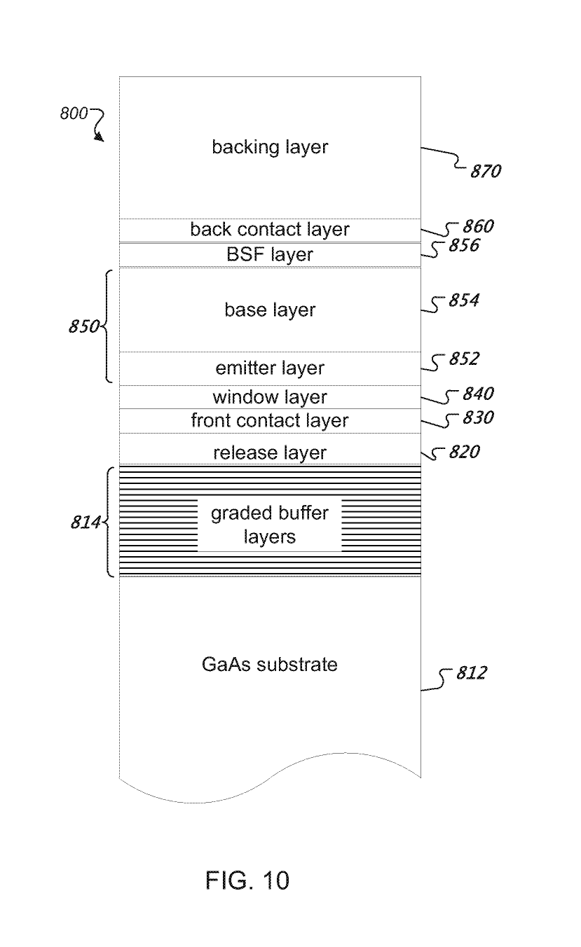

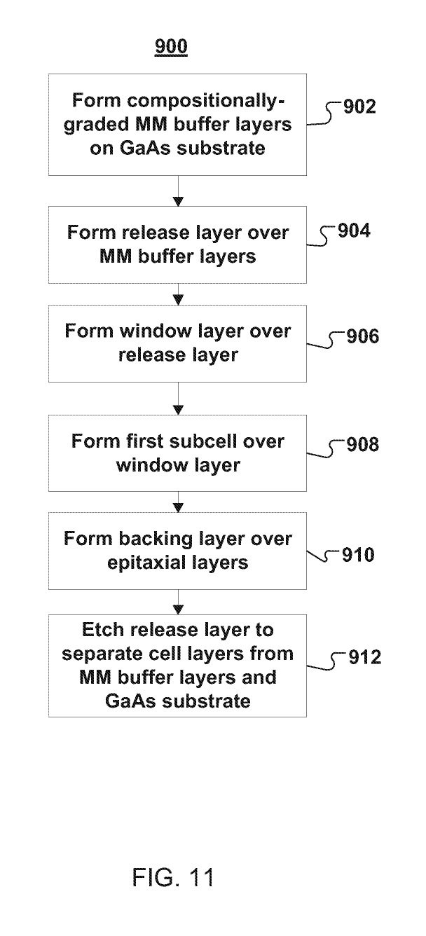

FIG. 10 includes a schematic diagram of a stack 800 for a metamorphic (MM) ELO single-junction InP-based solar cell grown on a GaAs substrate 712. FIG. 11 is a flow diagram graphically depicting a method 900 of making a metamorphic (MM) ELO InP-based solar cell on a GaAs substrate. For illustrative purposes, method 900 will be described with respect to reference numbers of stack 800. A compositionally-graded plurality of metamorphic (MM) buffer layers 814 are formed on a GaAs substrate 812 (step 902). A release layer 820 is epitaxially formed over the plurality of MM buffer layers 814 (step 904). In some embodiments, a buffer layer having lattice constants similar to those of InP is formed on the plurality of MM buffer layers 814 before formation of the release layer 820. A window layer 840 is epitaxially formed over the release layer 820 (step 906). In some embodiments, a front contact layer 830 is formed over the release layer 820 before formation of the window layer 840. A first subcell 850 including a base layer 854 and an emitter layer 852 is formed over the window layer 840 (step 908). In some embodiments, a BSF layer 856 and a back contact layer 860 are formed over the first subcell 850. A backing layer is formed over the epitaxial layers (step 910). The release layer 920 is etched to separate the solar cell from the plurality of metamorphic buffer layers 814 and the GaAs substrate 812 (step 912) thereby forming the InP-based solar cell. After formation of the plurality of compositionally-graded buffer layers, the method is substantially similar to methods of making InP-based solar cells on InP substrates.

### Example 1

### Comparison of ELO and Non-ELO Single-Junction InGaAs Cells

A thin epitaxial lift-off (ELO) single-junction (SJ) InGaAs solar cell was produced and characterized. A corresponding non-ELO SJ InGaAs solar cell on an InP substrate was also produced and characterized for comparison. The comparison showed that the operational characteristics of the thin film ELO InGaAs solar cell was similar to the operational characteristics of the non-ELO InGaAs solar cell on a substrate, indicating the ELO process of removing the cell layers from the substrate did not significantly affect the performance of the ELO SJ InGaAs solar cell.

Table 1 below lists the epitaxial layers in the stack-up used to form the ELO SJ InGaAs solar cell. The stack-up includes a p-type InGaAs base layer, an n-type InGaAs emitter layer, an n-doped InP window layer, and an n-doped AlAsSb release layer. The layers were deposited using MOCVD. After deposition of the stack-up, a backing layer was formed over the epitaxial layers and the release layer was etched using HF acid producing a thin film of cell layers free of the substrate. After release from the substrate the thin film of cell layers, including the backing layer, was inverted with the patterned front contact layer (FCL) and the window forming the top layers in the ELO SJ InGaAs solar cell with the backing layer forming the bottom layer of the solar cell.

TABLE 1
ELO Single-Junction InGaAs Stack on InP substrate

| | | | Thickness | N_{d} (cm⁻³) | | Description of |
|---|---|---|---|---|---|---|
| Layer | Material | X | (Å) | (in E notation) | Dopant | Layer |
| 10 | pInₓGa₁₋ₓAs | 0.53 | 3000 | 5.00E+18 | Zn | Back Contact |
| | | | | | | Layer (BCL) |
| 9 | PInp | | 1000 | 2.00E+18 | Zn | Back Surface Field |
| | | | | | | (BSF) |
| 8 | pInₓGa₁₋ₓAs | 0.53 | 40000 | 1.00E+17 | Zn | Base |
| 7 | nInₓGa₁₋ₓAs | 0.53 | 1000 | 2.00E+18 | Si | Emitter |
| 6 | nInP | | 300 | 1.00E+19 | Te | Window |
| 5 | nInₓGa₁₋ₓAs | 0.53 | 3000 | 1.00E+19 | Te | Front Contact |
| | | | | | | Layer (FCL) |
| 4 | nInP | | 200 | 1.00E+19 | Te | Etch Stop |
| 3 | nInₓGa₁₋ₓAs | 0.53 | 500 | 1.00E+19 | Te | Buffer |
| 2 | nAlAsₓSb₁₋ₓ | 0.53 | 50 | 2.00E+18 | Si | Release Layer |
| 1 | InP | | 500 | | None | Buffer |
| | InP | | | | None | Substrate |

Table 2 below lists the epitaxial layers in in the stack-up for the comparison non-ELO SJ InGaAs solar cell on an InP substrate. Unlike the ELO stack above that is inverted after etching the release layer, the top layers of the non-ELO stack, specifically, the patterned FCL and window layer, remain at the top of the non-ELO solar cell.

TABLE 2
non-ELO Single-Junction InGaAs Stack on InP Substrate

| Layer | Material | X | Thk (Å) | N_{d} (cm⁻³) | Dopant | Description |
|---|---|---|---|---|---|---|
| 7 | nInₓGa₁₋ₓAs | 0.53 | 1000 | 1.00E+19 | Te | FCL |
| 6 | nInP | | 300 | 1.00E+19 | Te | Window |
| 5 | nInₓGa₁₋ₓAs | 0.53 | 1000 | 2.00E+18 | Si | Emitter |
| 4 | pInₓGa₁₋ₓAs | 0.53 | 20000 | 1.00E+17 | Zn | Base |
| 3 | pInp | | 500 | 2.00E+18 | Zn | BSF |
| 2 | pInₓGa₁₋ₓAs | 0.53 | 1000 | 5.00E+18 | Zn | BCL |
| 1 | pInP | | 500 | 5.00E+18 | Zn | Buffer |
| | InP | | | | | Substrate |

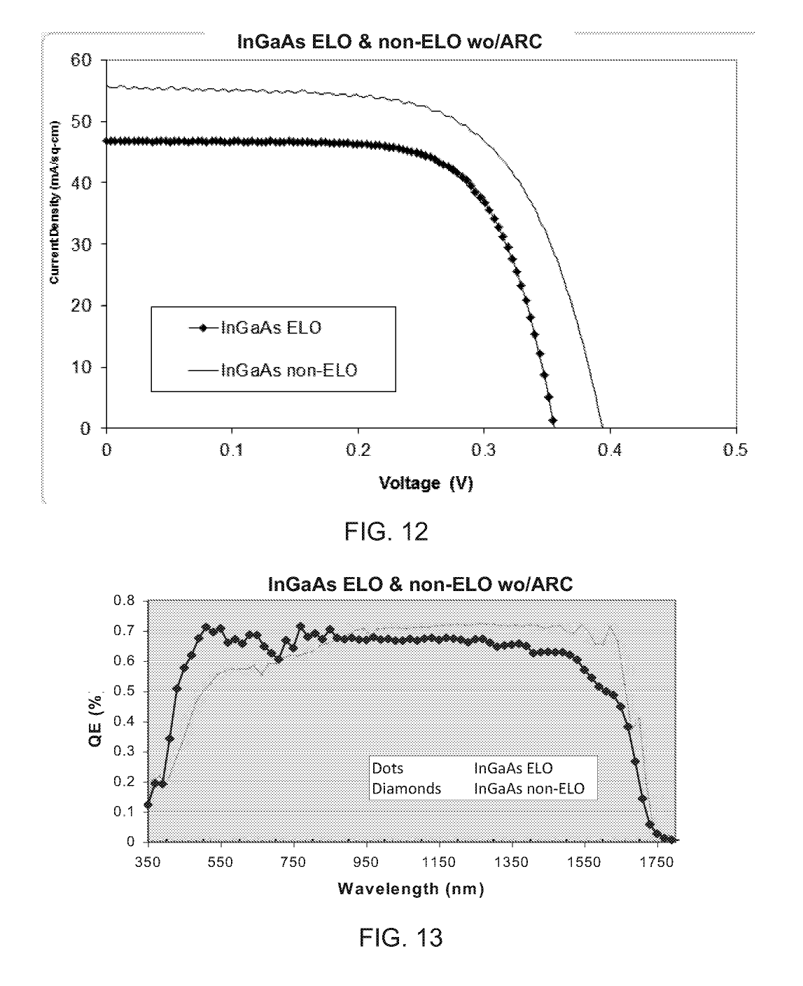

FIG. 12 is a graph of experimental data for current density as a function of applied voltage (I-V data) for the ELO SJ InGaAs solar cell and for the comparison non-ELO SJ InGaAs solar cell on an InP substrate. Both solar cells were tested without anti-reflection (AR) coatings. This graph shows that the I-V operational characteristics of the thin film ELO SJ InGaAs solar cell is comparable to the I-V operational characteristics of the comparison non-ELO SJ InGaAs solar cell.

FIG. 13 is a graph of experimental data for quantum efficiency as a function of wavelength for the ELO SJ InGaAs solar cell and for the comparison non-ELO InGaAs solar cell on an InP substrate. The quantum efficiency data are also similar for the ELO and non-ELO SJ InGaAs solar cells.

### Example 2

### Single-Junction InP Solar Cells

### A. Comparison of ELO and Non-ELO Single-Junction InP Cells

A thin film ELO SJ InP solar cell was produced and tested to determine its operational characteristics. A corresponding non-ELO SJ InP solar cell on an InP substrate was also produced and tested for comparison.

Table 3 below lists the epitaxial layers in the stack-up used to form the ELO SJ InP solar cell. The stack-up included a p-type InP base layer, an n-type InP emitter layer, an n-doped InAlAs window layer, and an n-doped AlAsSb release layer. A backing layer, which is not listed in the table, was deposited over the epitaxial layer. After formation for the backing layer, the release layer was etched and the resulting thin film of layers inverted and processed to form the ELO SJ InP solar cell.

TABLE 3
ELO Single-junction InP Stack on InP Substrate

| Layer | Material | X | Thk (Å) | N_{d} (cm⁻³) | Dopant | Description |
|---|---|---|---|---|---|---|
| 11 | pInₓGa₁₋ₓAs | 0.53 | 3000 | 5.00E+18 | Zn | BSC |
| 10 | pInₓAl₁₋ₓAs | 0.52 | 1000 | 2.00E+18 | Zn | BSF |
| 9 | pInP | | 40000 | 1.00E+17 | Zn | Base |
| 8 | nInP | | 200 | 5.00E+18 | Si | Emitter |
| 7 | nInₓAl₁₋ₓAs | 0.52 | 200 | 1.00E+19 | Si | Window |
| 6 | nInP | | 200 | 1.00E+17 | Te | Etch Stop |
| 5 | nInₓGa₁₋ₓAs | 0.53 | 3000 | 2.00E+18 | Te | FSC |
| 4 | nInP | | 200 | 1.00E+19 | Te | Etch Stop |
| 3 | nInₓGa₁₋ₓAs | 0.53 | 500 | 2.00E+18 | Te | Buffer |
| 2 | nAlAsₓSb₁₋ₓ | 0.5 | 50 | 5.00E+18 | Si | Release |
| | | | | | | Layer |
| 1 | nInP | | 500 | 5.00E+18 | Si | Buffer |
| | InP substrate | | | | | |

Table 4 below lists the epitaxial layers in the stack for the comparison non-ELO SJ InP solar cell on an InP substrate. Unlike the ELO stack above that is inverted after etching the release layer, the top layers of the non-ELO stack, specifically, the patterned FCL and window layer, remain at the top of the non-ELO solar cell.

TABLE 4
non-ELO Single-junction InP Stack on InP Substrate

| | | | Thk | | | Description |
|---|---|---|---|---|---|---|
| Layer | Material | X | (Å) | N_{d} (cm⁻³) | Dopant | of Layer |
| 6 | nInGaAs | 0.52 | 3000 | 3.00E+18 | Te | FCL |
| 5 | nInP | | 100 | 1.00E+19 | Si | Window |
| 4 | nInP | | 500 | 1.00E+18 | Si | Emitter |
| 3 | pInP | | 20000 | 1.00E+17 | Zn | Base |
| 2 | pInₓAl₁₋ₓAs | 0.52 | 500 | 5.00E+18 | Zn | BSF |
| 1 | pInP | | 500 | 5.00E+18 | Zn | buffer |
| | InP substrate | | | | | |

The ELO SJ InP stack incorporates multiple InP layers, (e.g., for the base layer, for the emitter layer and for etch stop layers). This structure could not be made using a technique that dissolves or etches the InP substrate itself, as opposed to releasing the layers from the InP substrate, because the InP layers in the solar cell would be damaged by the substrate removal process.

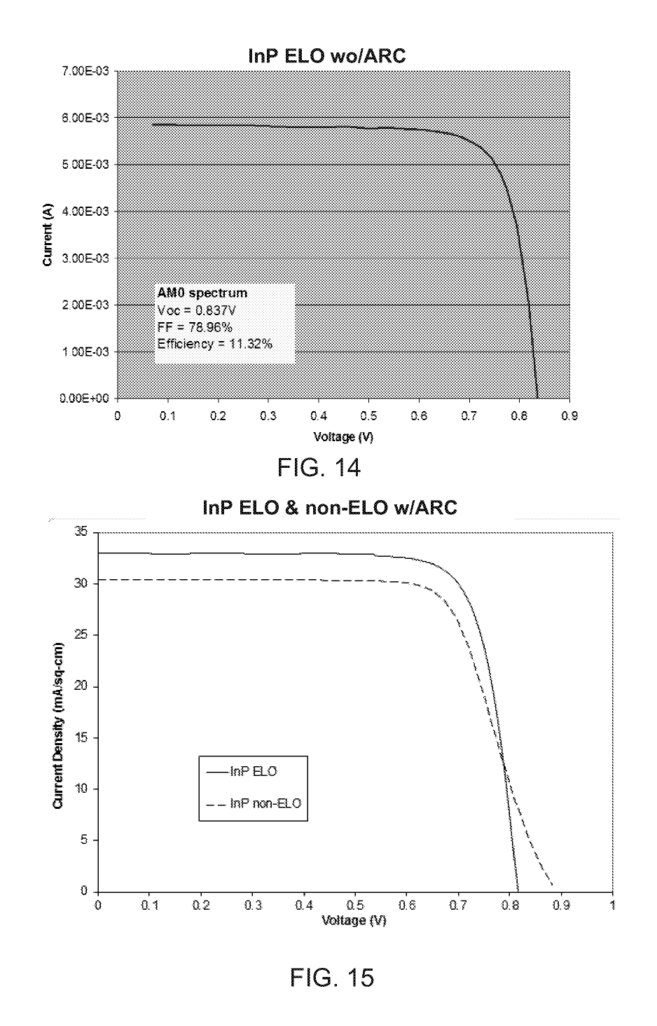

FIG. 14 is a graph of I-V operational characteristics for an ELO SJ InP solar cell under AM0 illumination conditions without an anti-reflection coating. As shown, the cell has an open current voltage of 0.837 V, an efficiency of 11.32% and a fill factor of 78.96%.

FIG. 15 is a graph comparing I-V operational characteristics for an ELO SJ InP solar cell and a non-ELO SJ InP solar cell, both with anti-reflection coatings (ARC).

Table 5 below lists parameters for the best single-junction ELO and non-ELO InGaAs solar cells and for the best single-junction ELO and non-ELO InP solar cells. For both SJ InGaAs solar cells and SJ InP solar cells, the performance of the ELO solar cells is similar to that of the corresponding non-ELO solar cells. Thus, the ELO process of removing the cell layers from the substrate did not significantly affect the operating characteristics of the ELO solar cells.

TABLE 5
Best Single-Junction InP and InGaAs
Solar Cell Performance at AM0

| | |
|---|---|
| InGaAs wo/ARC | InP w/ARC |

| | non-ELO | ELO | non-ELO | ELO |
|---|---|---|---|---|
| V_{oc} (V) | 0.39 | 0.36 | 0.89 | 0.82 |
| J_{sc} (mA/cm²) | 55.4 | 46.4 | 30.0 | 33.0 |
| Fill Factor (%) | 64.2 | 69.2 | 71.3 | 83.1 |
| Efficiency (%) | 10.2 | 8.5 | 14.1 | 16.5 |

### B. Window Materials for Single-Junction InP Cells

Epitaxially grown window materials commonly used for GaAs-based solar cells are not compatible with InP based solar cells. Applicants experimented with different types of InP-compatible (InP lattice-matched) epitaxially grown window layers to determine how the material of the window layer affected performance of single-junction InP solar cells. Various window materials were tested including heavily-doped InP (1.344 eV bandgap at 300 K), InAlAs (1.42 eV bandgap at 300 K), and AlAsSb (1.91 eV bandgap at 300 K). Due to the AlAsSb layer reacting to air, an InP cap layer was used with the AlAsSb window layer. Some initial designs for SJ InP solar cells included an n-doped base, which would require a p-doped window. Accordingly, a p-doped window (p⁺InP) was tested on a SJ InP solar cell having an n-doped base. After the SJ InP solar cells with p-doped bases described above were selected for further development, the other window materials tested were n-doped window materials (i.e., n⁺InP, nInAlAs, nAlAsSb).

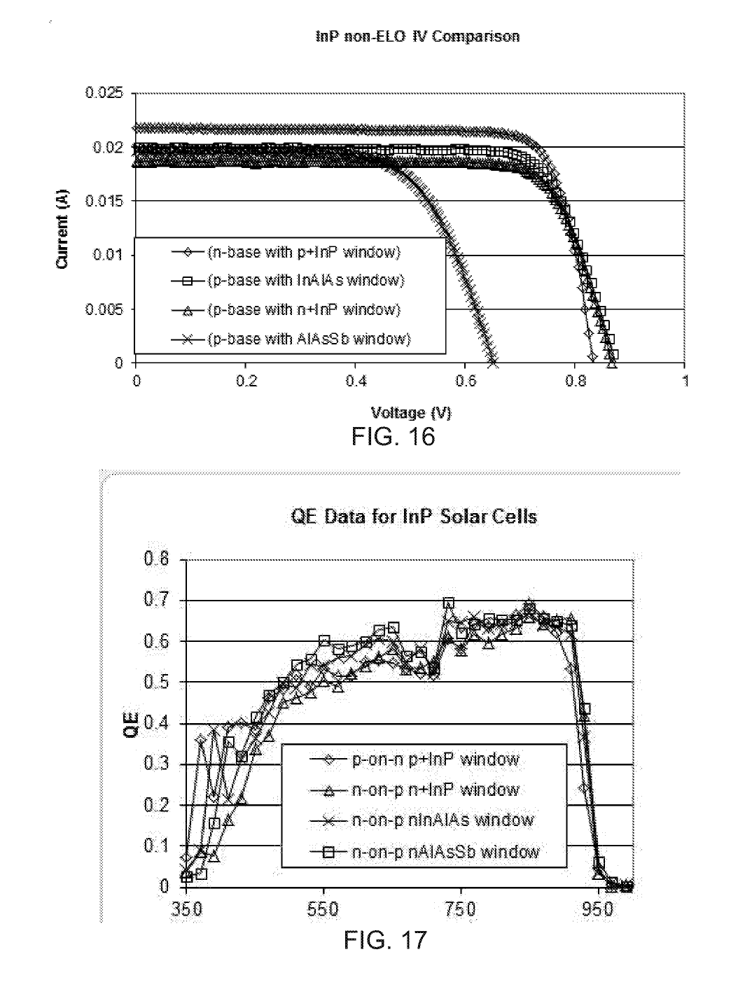

FIG. 16 includes a graph of I-V operational characteristics for SJ InP solar cells with different window materials. The data were collected using non-ELO solar cells. As explained above, ELO solar cells have comparable operational characteristics to non-ELO solar cells. Thus, results regarding window layers for non-ELO solar cells are applicable to ELO solar cells. As shown by the graph in FIG. 16, the p⁺InP, InAlAs, and n⁺InP window layers showed similar I-V operational characteristics when tested in the InP solar cells. Only the AlAsSb window layer significantly changed the I-V operational characteristics of the cell by significantly lowering the open circuit voltage and the fill factor. The graph in FIG. 17 shows quantum efficiency for the various window materials: p⁺InP, InAlAs, AlAsSb and n⁺InP. The quantum efficiency of the InP cells was not significantly affected by the variations in window material.

### C. Radiation Tolerance of ELO Single-Junction InP Solar Cells

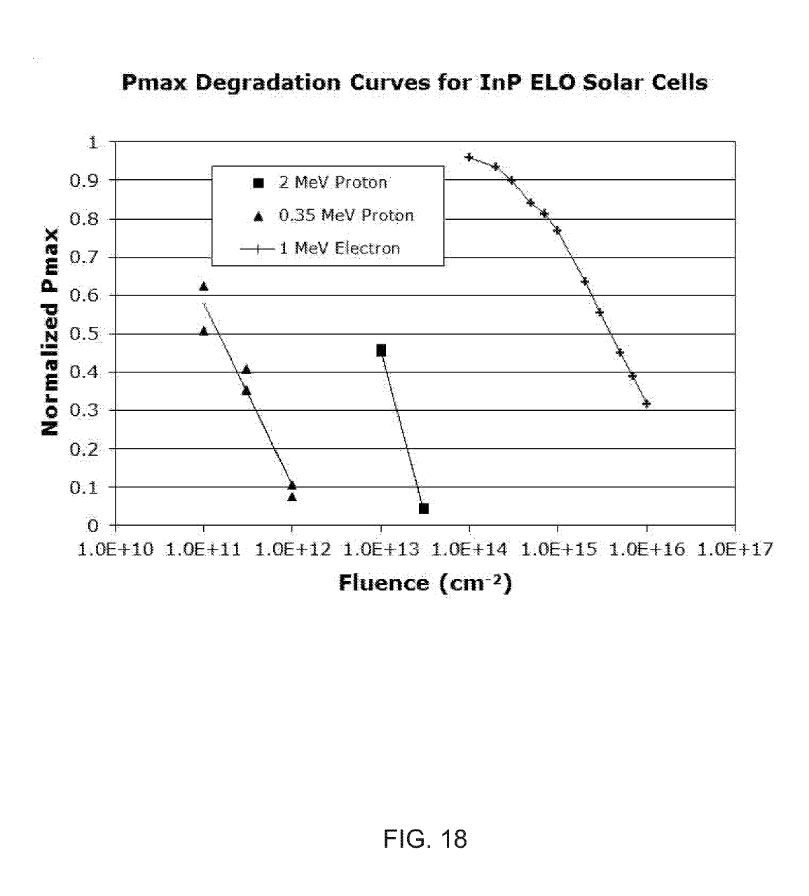

Applicants subjected ELO SJ InP solar cells to radiation having various energies to determine how cumulative radiation damage affected device performance. FIG. 18 includes a graph of the normalized maximum output power (Pₘₐₓ) as a function of cumulative radiation dose per square centimeter for 2 MeV protons (squares), for 0.35 MeV protons (triangles) and for 1 MeV electrons (crosses).

### Example 3

### Single-Junction InGaAsP Solar Cell

Applicants produced and characterized non-ELO single-junction InGaAsP solar cells having a 1.0 eV bandgap, and single-junction InGaAsP solar cells having a 1.2 eV bandgap. The results should be applicable to ELO single-junction InGaAsP solar cells as well.

### A. 1.0 eV Single-Junction InGaAsP Solar Cells

Applicants produced and tested SJ non-ELO 1.0 eV InGaAsP solar cells on InP substrates having the layer structure as described in Table 6 below. The base and emitter layers had a structure of GaₓIn₁₋ₓP_{y}As_{1-y} with x=0.242 and y=0.526, which resulted in a bandgap of 1.0 eV.

TABLE 6
Non-ELO 1.0 eV Single-Junction InGaAsP Stack on InP Substrate

| Layer | Material | x | y | Thick (Å) | N_{d} (cm⁻³) | Dopant | Description |
|---|---|---|---|---|---|---|---|
| 8 | nInₓGa₁₋ₓAs | 0.53 | | 1000 | 2.00E+19 | Te | FSC |
| 7 | nInP | | | 1000 | 1.00E+19 | Te | Window |
| 6 | nGaₓIn₁₋ₓP_{y}As_{1-y} | 0.242 | 0.526 | 5000 | 3.00E+17 | Si | Emitter |
| 5 | GaₓIn₁₋ₓP_{y}As_{1-y} | 0.242 | 0.526 | 500 | | None | Interrupt |
| 4 | pGaₓIn₁₋ₓP_{y}As_{1-y} | 0.242 | 0.526 | 40000 | 1.00E+17 | Zn | Base |
| 3 | pInP | | | 2000 | 5.00E+17 | Zn | BSF |
| 2 | pInₓGa₁₋ₓAs | 0.53 | | 500 | 1.00E+19 | Zn | BSC |
| 1 | pInP | | | 500 | 1.00E+19 | Zn | Buffer |
| | InP substrate | | | | | | |

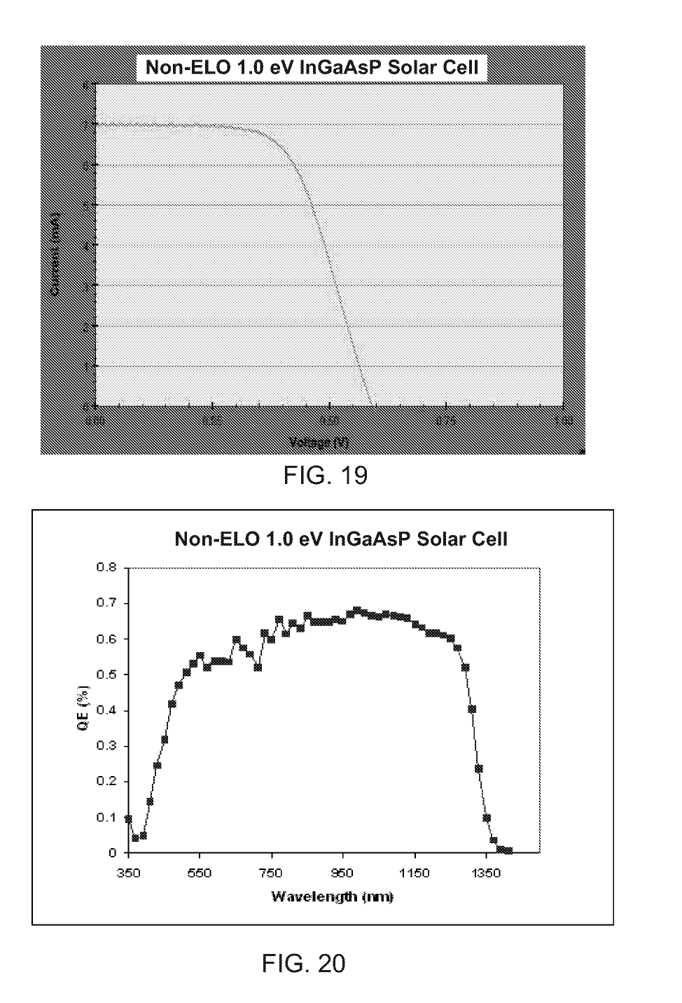

The measured I-V operational characteristics of the non-ELO 1.0 eV InGaAsP solar cell appear in FIG. 19. FIG. 20 shows the quantum efficiency of the non-ELO 1.0 eV InGaAs solar cell. Although these data were obtained using a non-ELO solar cell, data for a corresponding ELO solar cell should be substantially similar to the non-ELO data because the Applicant's ELO process does not significantly change solar cell performance as demonstrated by the comparative ELO and non-ELO InP and InGaAs solar cell data above. Thus, results similar to those in FIGS. 19 and 20 should be expected for the corresponding ELO 1.0 eV InGaAsP solar cell resulting from the epitaxial stack described by Table 7 below.

TABLE 7
Equivalent ELO 1.0 eV Single-Junction InGaAsP Stack on InP Substrate

| Layer | Material | x | y | Thk (Å) | N_{d} (cm⁻³) | Dopant | Description |
|---|---|---|---|---|---|---|---|
| 11 | pInₓGa₁₋ₓAs | 0.53 | | 3000 | 5.00E+18 | Zn | BSC |
| 10 | pInP | | | 1000 | 2.00E+18 | Zn | BSF |
| 9 | pGaₓIn₁₋ₓP_{y}As_{1-y} | 0.242 | 0.526 | 40000 | 1.00E+17 | Zn | Base |
| 8 | GaₓIn₁₋ₓP_{y}As_{1-y} | 0.242 | 0.526 | 100 | | None | Interrupt |
| 7 | nGaₓIn₁₋ₓP_{y}As_{1-y} | 0.242 | 0.526 | 5000 | 1.00E+18 | Si | Emitter |
| 6 | nInP | | | 300 | 1.00E+19 | Te | Window |
| 5 | nInₓGa₁₋ₓAs | 0.53 | | 3000 | 1.00E+19 | Te | FSC |
| 4 | nInP | | | 200 | 1.00E+19 | Te | Etch Stop |
| 3 | nInₓGa₁₋ₓAs | 0.53 | | 500 | 1.00E+19 | Te | Buffer |
| 2 | nAlAsₓSb₁₋ₓ | 0.5 | | 50 | 2.00E+18 | Si | Release Layer |
| 1 | InP | | | 500 | | NA | Buffer |
| | InP substrate | | | | | | |

### B. 1.2 eV Single-Junction InGaAsP Solar Cells

Applicants produced and tested SJ non-ELO 1.2 eV InGaAsP solar cells on InP substrates having the layer structure as described in Table 8 below. The base and emitter layers had a structure of GaₓIn₁₋ₓP_{y}As_{1-y} with x=0.12 and y=0.73, which resulted in a bandgap of 1.2 eV.

TABLE 8
Non-ELO 1.2 eV Single-Junction InGaAsP Stack on InP Substrate

| Layer | Material | x | y | Thick (Å) | N_{d} (cm⁻³) | Dopant | Description |
|---|---|---|---|---|---|---|---|
| 5 | nInP | | | 100 | 1.00E+19 | Te | Window & FSC |
| 4 | nGaₓIn₁₋ₓP_{y}As_{1-y} | 0.12 | 0.73 | 500 | 5.00E+17 | Si | Emitter |
| 3 | pGaₓIn₁₋ₓP_{y}As_{1-y} | 0.12 | 0.73 | 20000 | 1.00E+17 | Zn | Base |
| 2 | pInₓAl₁₋ₓAs | 0.52 | | 500 | 5.00E+18 | Zn | BSF |
| 1 | pInP | | | 500 | 5.00E+18 | Zn | Buffer |
| | InP substrate | | | | | | |

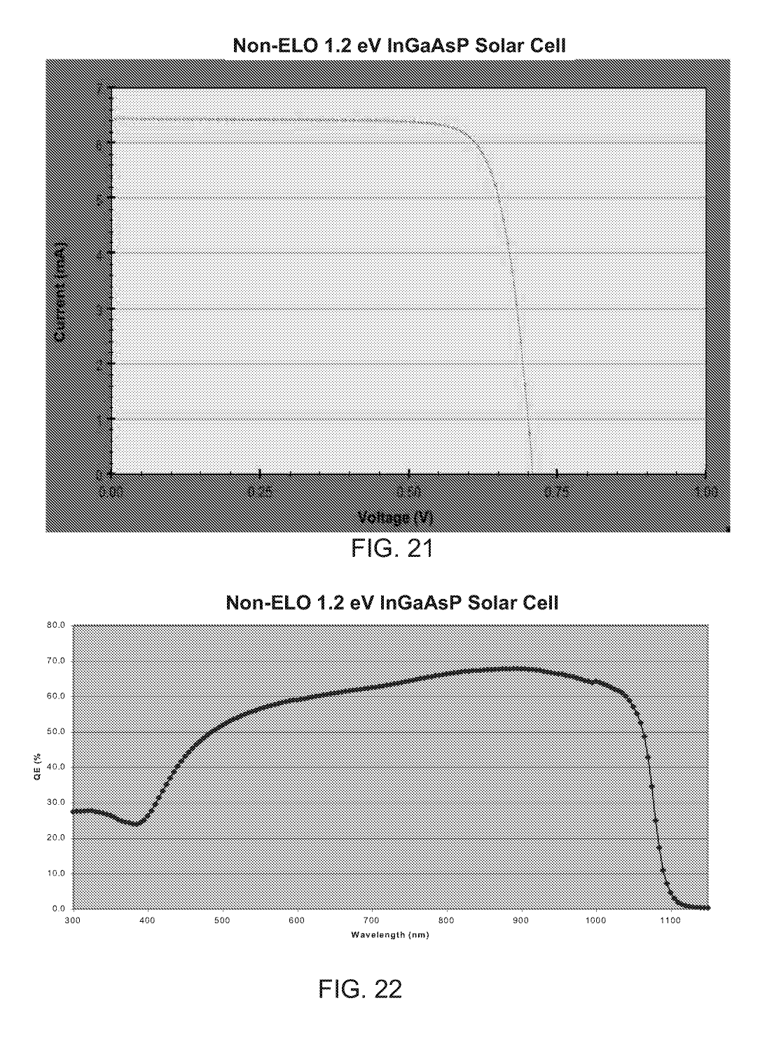

The measured I-V operational characteristics of a non-ELO 1.2 eV InGaAsP solar cell appears in FIG. 21. FIG. 22 shows the quantum efficiency of a non-ELO 1.2 eV InGaAs solar cell. Although this data was obtained using a non-ELO solar cell, data for a corresponding ELO solar cell should be substantially similar to the non-ELO data because the Applicant's ELO process does not significantly change solar cell performance as demonstrated by the comparative ELO and non-ELO InP and InGaAs solar cell data above. Thus, results similar to those in FIGS. 21 and 22 should be expected for the corresponding ELO 1.2 eV InGaAsP solar cells resulting from the epitaxial stack described by Table 9 below.

TABLE 9
Equivalent ELO 1.2 eV Single-Junction InGaAsP Stack on InP Substrate

| Layer | Material | x | y | Thick (Å) | N_{d} (cm⁻³) | Dopant | Description |
|---|---|---|---|---|---|---|---|
| 11 | pInₓGa₁₋ₓAs | 0.53 | | 3000 | 5.00E+18 | Zn | BSC |
| 10 | pInP | | | 1000 | 2.00E+18 | Zn | BSF |
| 9 | pGaₓIn₁₋ₓP_{y}As_{1-y} | 0.12 | 0.73 | 40000 | 1.00E+17 | Zn | Base |
| 8 | GaₓIn₁₋ₓP_{y}As_{1-y} | 0.12 | 0.73 | 100 | | | Interrupt |
| 7 | nGaₓIn₁₋ₓP_{y}As_{1-y} | 0.12 | 0.73 | 5000 | 1.00E+18 | Si | Emitter |
| 6 | nInP | | | 300 | 1.00E+19 | Te | Window |
| 5 | nInₓGa₁₋ₓAs | 0.53 | | 3000 | 1.00E+19 | Te | FSC |
| 4 | nInP | | | 200 | 1.00E+19 | Te | Etch Stop |
| 3 | nInₓGa₁₋ₓAs | 0.53 | | 500 | 1.00E+19 | Te | Buffer |
| 2 | nAlAsₓSb₁₋ₓ | 0.5 | | 50 | 2.00E+18 | Si | Release Layer |
| 1 | InP | | | 500 | | | Buffer |
| | InP substrate | | | | | | |

### Example 4

### Dual-Junction InP/in GaAs Solar Cell

Applicants developed and tested dual-junction InP/InGaAs solar cells including a tunnel diode between the subcells.

### A. Tunnel Diode Structures

Initially, Applicants produced and tested p on n and n on p tunnel diodes using tunnel diode test structures before incorporating them into solar cells. Table 10 below lists the layers used in the p on n tunnel diode test stack and Table 11 lists the layers used on the n on p tunnel diode test stack. The tunnel diodes include a p⁺GaAsSb layer heavily doped with C and an n⁺InP layer heavily doped with Si.

TABLE 10
P on N Tunnel Diode Stack

| Layer | Material | x | Thk (Å) | N_{d} (cm⁻³) | Dopant |
|---|---|---|---|---|---|
| 7 | pInₓGa₁₋ₓAs | 0.53 | 1000 | 5.00E+18 | Zn |
| 6 | pInₓAl₁₋ₓAs | 0.52 | 1000 | 5.00E+18 | Zn |
| 5 | pGaAs₁₋ₓSbₓ | 0.5 | 200 | 3.00E+19 | C |
| 4 | nInP | | 200 | 1.50E+19 | Si |
| 3 | nInP | | 200 | 4.00E+18 | Si |
| 2 | nInₓGa₁₋ₓAs | 0.53 | 1000 | 1.00E+19 | Si |
| 1 | nInP | | 500 | 1.00E+19 | Si |
| | InP Substrate | | | | |

TABLE 11
N on P Tunnel Diode Stack

| Layer | Material | x | Thk (Å) | N_{d} (cm⁻³) | Dopant |
|---|---|---|---|---|---|
| 6 | nInₓGa₁₋ₓAs | 0.53 | 1000 | 1.00E+19 | Si |
| 5 | nInP | | 200 | 2.00E+19 | Si |
| 4 | pGaAs₁₋ₓSbₓ | 0.5 | 200 | 4.00E+19 | C |
| 3 | pInP | | 300 | 2.00E+18 | Zn |
| 2 | pInₓGa₁₋ₓAs | 0.53 | 2000 | 5.00E+18 | Zn |
| 1 | InP | | 500 | | NA |
| | InP Substrate | | | | |

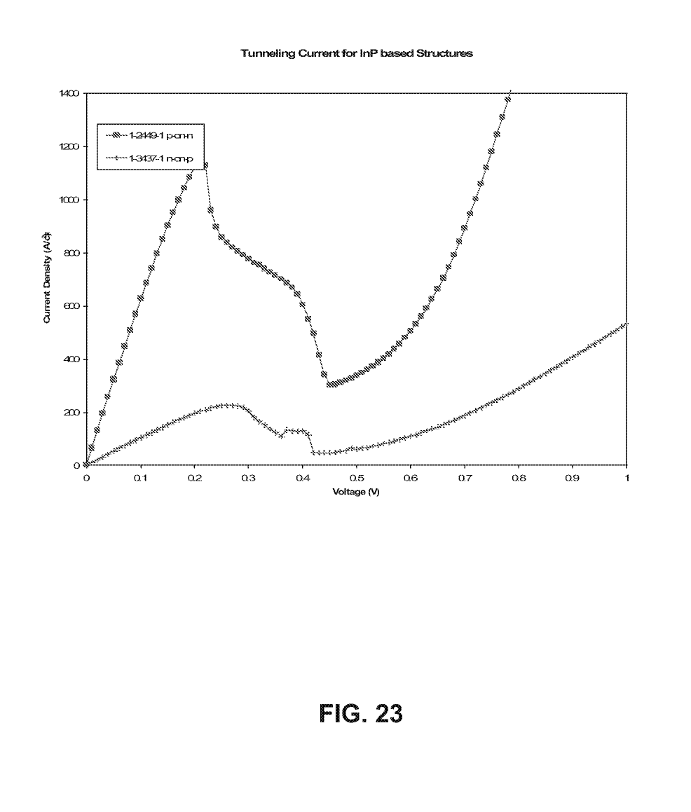

FIG. 23 includes an I-V graph for the p on n and n on p tunnel diodes. Both diodes showed a region of decreasing current with increasing voltage that indicated tunneling.

### B. Dual-Junction InP/InGaAs Solar Cell

Applicants made and tested non-ELO dual-junction (DJ) InP/InGaAs solar cells including a tunnel diode between the subcells. Table 12 below lists the epitaxial layers used for the non-ELO DJ InP/GaAs solar cell that includes a p⁺GaAsSb/n⁺InP tunnel diode.

TABLE 12
Non-ELO Dual-Junction InP/GaAs with Tunnel Diode Stack
on InP Substrate

| Layer | Material | X | Thk (Å) | N_{d} (cm⁻³) | Dopant | Description |
|---|---|---|---|---|---|---|
| 12 | nInₓGa₁₋ₓAs | 0.53 | 2000 | 1.50E+19 | Te | FCL |
| 11 | nInP | | 200 | 1.50E+19 | Si | Window |
| 10 | nInP | | 500 | 5.00E+17 | Si | Emitter |
| 9 | pInp | | 40000 | 5.00E+16 | Zn | Base |
| 8 | pInₓAl₁₋ₓAs | 0.52 | 1000 | 5.00E+18 | Zn | BSF |
| 7 | pGaAs₁₋ₓSbₓ | 0.5 | 100 | 3.50E+19 | C | TD p⁺ |
| 6 | nInP | | 300 | 1.50E+19 | Te | Window & |
| | | | | | | TD n⁺ |
| 5 | nInₓGa₁₋ₓAs | 0.53 | 500 | 1.00E+18 | Si | Emitter |
| 4 | pInₓGa₁₋ₓAs | 0.53 | 60000 | 5.00E+16 | Zn | Base |
| 3 | pInp | | 100 | 2.00E+18 | Zn | BSF |
| 2 | pInₓGa₁₋ₓAs | 0.53 | 1000 | 5.00E+18 | Zn | BCL |
| 1 | pInP | | 200 | 5.00E+18 | Zn | Buffer |
| | InP | | | | | Substrate |

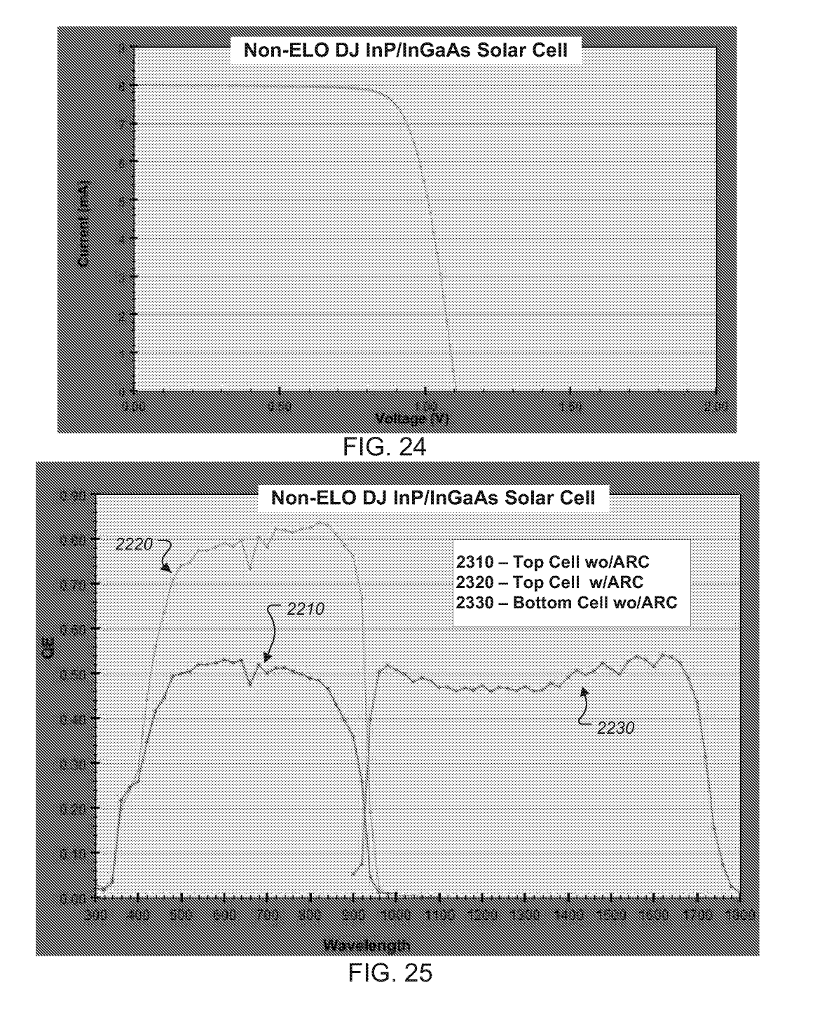

The measured I-V operational characteristics of a non-ELO DJ InP/InGaAs solar cell under AM0 appear in FIG. 24. The open circuit voltage (V_{oc}) exceeded 1.1 V and the short circuit current density (J_{sc}) was 31.6 mA/cm² using only top cell isolation. The fill factor was 75.6%, and the overall AM0 efficiency was 19.5%. FIG. 25 shows the quantum efficiency of subcells of non-ELO DJ InP/InGaAs solar cells. The quantum efficiency data includes data for the top subcell without an ARC 2310, data for the top subcell with an ARC 2320, and data for the bottom subcell without an ARC 2330. Although this data was obtained using a non-ELO DJ solar cell, data for a corresponding ELO solar cell should be substantially similar to the non-ELO data because the Applicant's ELO process does not significantly change solar cell performance as demonstrated by the comparative ELO and non-ELO InP and InGaAs solar cell data above. Thus, results similar to those in FIGS. 24 and 25 should be expected for corresponding ELO DJ InP/InGaAs solar cells resulting from the epitaxial stack described by Table 13 below.

TABLE 13
Equivalent ELO Dual-Junction InP/GaAs with
Tunnel Diode Stack on InP Substrate

| Layer | Material | X | Thk (Å) | Description |
|---|---|---|---|---|
| 15 | pInₓGa₁₋ₓAs | 0.53 | 3000 | BCL |
| 14 | pInp | | 1000 | BSF |
| 13 | pInₓGa₁₋ₓAs | 0.53 | 30000 | Base |
| 12 | nInₓGa₁₋ₓAs | 0.53 | 1000 | Emitter |
| 11 | nInP | | 300 | TD n⁺ & Window |
| 10 | pGaAs₁₋ₓSbₓ | 0.5 | 300 | TD p⁺ |
| 9 | pInₓAl₁₋ₓAs | 0.52 | 1000 | BSF |
| 8 | pInp | | 20000 | Base |
| 7 | nInP | | 500 | Emitter |
| 6 | nInP | | 200 | Window |
| 5 | nInₓGa₁₋ₓAs | 0.53 | 3000 | FCL |
| 4 | nInP | | 200 | Etch Stop |
| 3 | nInₓGa₁₋ₓAs | 0.53 | 500 | Emitter |
| 2 | nAlAsₓSb₁₋ₓ | 0.5 | 50 | Release |
| 1 | InP | | 500 | Buffer |
| | InP | | | Substrate |

### C. Anti-Reflection Coatings

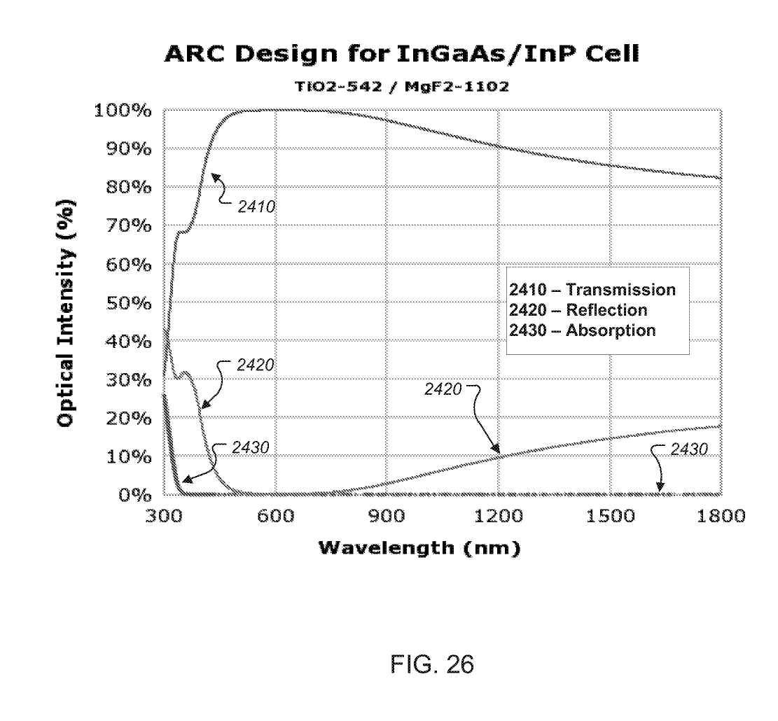

Applicants employed multilayer antireflection coatings for the dual-junction solar cells. The anti-reflection coating employed on the final dual-junction solar cells included a 1102 Å thick layer of MgF₂ and a 542 Å thick layer of TiO₂, both deposited by electron-beam evaporation. FIG. 26 includes a graph of the optical properties of the ARC, including transmission 2410, reflection 2420 and absorption 2430 as a function of wavelength.

### Example 5

### Triple-Junction InAlAsSb/InGaAsP/InGaAs Solar Cell

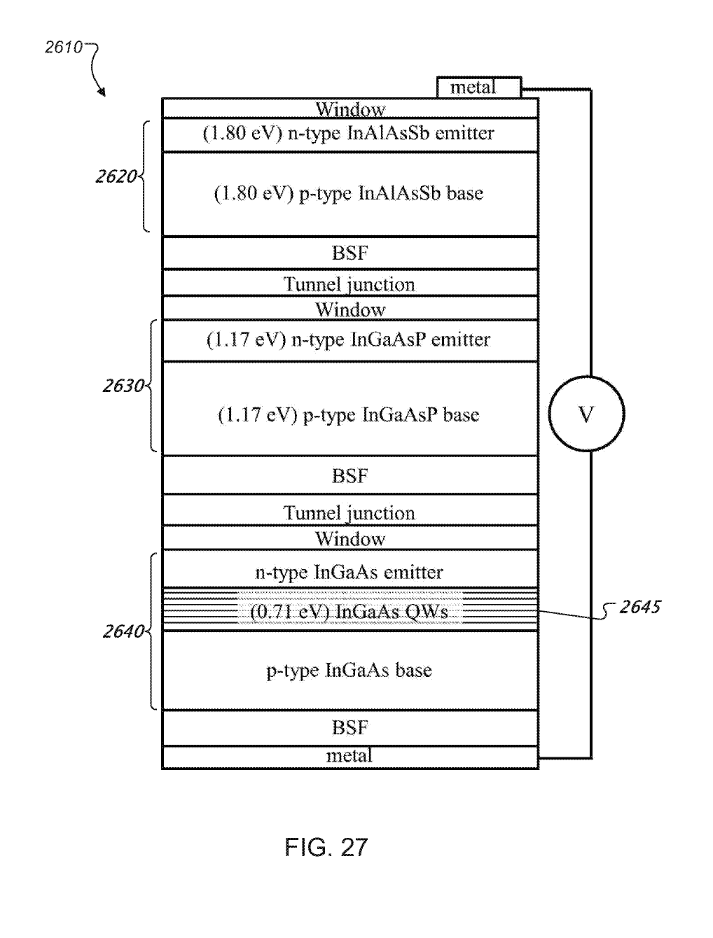

An example ELO triple-junction (TJ) solar cell 2610 is shown in FIG. 27. The TJ solar cell includes a top InAlAsSb subcell 2620 that has a bandgap of 1.8 eV, a middle InGaAsP subcell 2630 that has a bandgap of 1.17 eV, and a bottom InGaAs subcell 2640, which includes InGaAs quantum wells 2645, that has a bandgap of 0.71 eV.

### Example 6

### Triple-Junction Split Top Cell InAlAs/InGaAsP/InGaAs Solar Cell

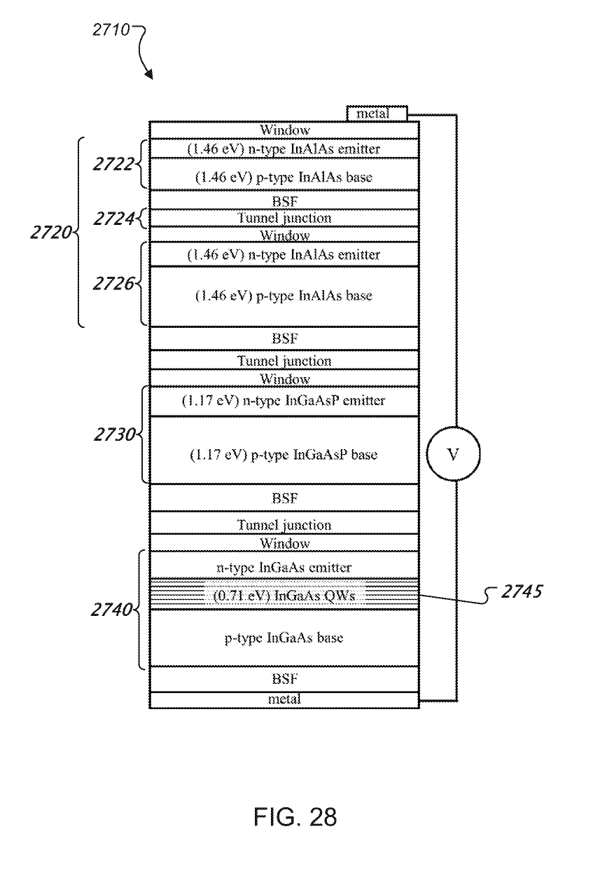

An example of an ELO triple-junction (TJ) solar cell 2710 that includes a top junction a split cell is shown in FIG. 28. Similar the TJ solar cell 2610 described above, the TJ solar cell 2710 includes a middle InGaAsP subcell 2730 that has a bandgap of 1.17 eV, and a bottom InGaAs subcell 2740, which includes InGaAs quantum wells 2745, that has a bandgap of 0.71 eV. However, the TJ solar cell 2710 has two top subcells, a lower top subcell 2726 and an upper top subcell 2726 (collectively 2720), that both have the same bandgap, which is referred to as a “split cell” configuration. The lower top subcell 2726 is an InAlAs subcell that has a 1.46 eV bandgap. The upper top subcell 2722, which is also referred to herein as the additional top subcell, is also an InAlAs subcell that has a 1.46 eV bandgap. The upper top subcell 2722 is thinner than the lower top subcell 2724 such that about half of the incident photons with an energy greater than 1.46 eV are absorbed by the upper top subcell 2722 and about half of the about half of the incident photons with an energy greater than 1.46 eV are absorbed by the lower top subcell 2726. As shown, a tunnel junction 2724 may connect the upper top subcell 2722 and the lower top subcell 2726. The bandgap of the tunnel junction 2724 should be substantially higher than the bandgap of the upper top subcell 2722 and the lower top subcell 2726.

### Example 7

### ELO Single-Junction InP Solar Cell Grown on Metamorphic Layers on GaAs

Applicants produced and tested the operational characteristics of a metamorphic (MM) ELO SJ InP solar cell grown on metamorphic layers over GaAs and compared them with the operational characteristics of a typical lattice-matched (LM) ELO SJ InP solar cell grown on InP (see Example 2 above). Table 14 below lists the epitaxial layers used for the MM ELO SJ InP solar cell grown on GaAs. The Applicants employed a graded (metamorphic) buffer layer (layer 2) that included 20 different InGaAs layers in which the composition was graded in a stepwise fashion from GaAs to In_{0.53}Ga_{0.47}As according to the following formula (InₓGa₁₋ₓAs, x=0→0.53). An InGaAs buffer layer was deposited over the graded buffer layer, and an AlAsSb release layer was deposited over the buffer layer. The other layers of the stack-up are similar to those employed for the LM ELO SJ InP layers grown on an InP substrate.

TABLE 14
ELO Single-Junction InP Stack with Metamorphic Buffer Layers
on GaAs Substrate

| Layer | Material | X | Thk (Å) | N_{d} (cm⁻³) | Dopant | Description |
|---|---|---|---|---|---|---|
| 11 | pInₓGa₁₋ₓAs | 0.53 | 3000 | 5.00E+18 | Zn | BSC |
| 10 | pInₓAl₁₋ₓAs | 0.52 | 1000 | 2.00E+18 | Zn | BSF |
| 9 | pInP | | 40000 | 1.00E+17 | Zn | Base |
| 8 | nInP | | 200 | 5.00E+18 | Si | Emitter |
| 7 | nInₓAl₁₋ₓAs | 0.52 | 200 | 5.00E+18 | Si | Window |
| 8 | nInP | | 200 | 5.00E+18 | Te | Etch Stop |
| 7 | nInₓGa₁₋ₓAs | 0.53 | 3000 | 5.00E+18 | Te | FSC |
| 6 | nInP | | 200 | 5.00E+18 | Te | Etch Stop |
| 5 | nInₓGa₁₋ₓAs | 0.53 | 500 | 5.00E+18 | Te | Buffer |
| 4 | nAlAsₓSb₁₋ₓ | 0.5 | 50 | 2.00E+18 | Si | Release |
| | | | | | | Layer |
| 3 | InₓGa₁₋ₓAs | 0.53 | 1000 | | None | Buffer |
| 2 | InₓGa₁₋ₓAs | 0 to | 40000 | | None | Graded |
| | | 0.53 | (2000/ | | | Buffer - |
| | | | step) | | | twenty |
| | | | | | | steps |
| 1 | GaAs | | 500 | | None | Buffer |
| | GaAs | | | | | Substrate |

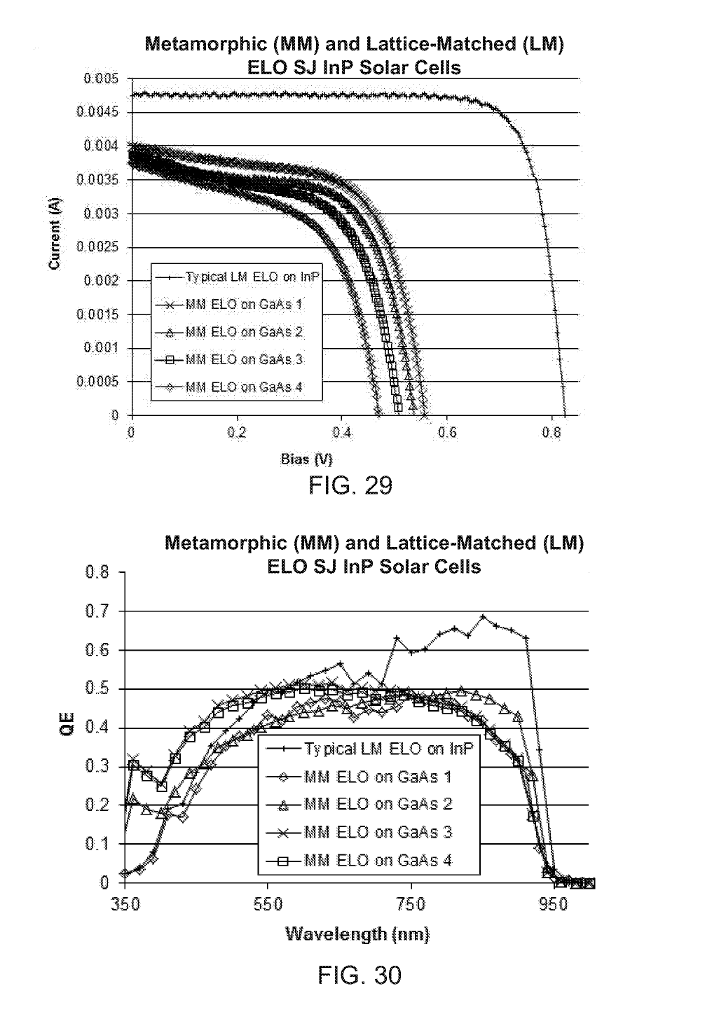

FIG. 29 shows I-V data for four different metamorphic (MM) ELO SJ InP solar cells grown on GaAs substrates and I-V data for a typical lattice-matched (LM) ELO SJ InP solar cell grown on an InP substrate. As shown in the graph, the LM ELO InP solar cell has a larger open circuit voltage than those of the MM ELO InP solar cells, and has a higher short circuit current than those of the MM ELO InP solar cells. Nevertheless, the MM ELO InP solar cells show consistent behavior from solar cell to solar cell. GaAs substrates are more widely used than InP substrates, are less fragile than InP substrates, and are readily available in larger wafer sizes than corresponding InP wafers. In some applications, the operational characteristics of the MM ELO InP solar cells may be sufficient and it may be desirable to use GaAs wafers instead of InP wafers (e.g., wafer scale processing on 6 inch GaAs wafers).

Exemplary embodiments of ELO InP-based solar cells can be used for all the applications for which non-ELO and ELO GaAs- and Ge-based solar cells can be used. For example, ELO InP-based solar cells can be used for space, airborne, and terrestrial power generation. For example, thin film ELO InP-based solar cells may be employed in terrestrial concentrator photovoltaic systems, in which increased efficiency is desirable. Thin film ELO InP-based solar cells may also have terrestrial applications under unconcentrated sunlight, such as portable blankets, for which increased efficiency and cell flexibility are desirable. Some exemplary ELO InP-based solar cells may be particularly well suited for power generation in high radiation environments, such as space.

As another example, thin film ELO InP-based solar cells may be employed in space applications such as satellite solar panels, for which increased efficiency and reduced weight are desirable. Further, because InP-based multi-junction solar cells have improved resistance to radiation as compared to GaAs-based multi-junction solar cells, they may be particularly well suited for power generation in high radiation environments, such as space. As yet another example, thin film ELO InP-based solar cells may be used to power for unmanned aerial vehicles, for which increased efficiency and reduced weight is desirable. In some embodiments, the ELO technology taught herein can be applied to thermophotovoltaic (TPV) applications.

While the present invention has been described with reference to illustrative embodiments thereof, those skilled in the art will appreciate that various changes in form in detail may be made without parting from the intended scope of the present invention as defined in the appended claims.

1.-19. (canceled)

20. A method for fabricating an InP-based solar cell free of a substrate, the method comprising:
epitaxially forming a release layer on an InP substrate;
epitaxially forming a window layer over the release layer;
epitaxially forming a first subcell over the window layer;
forming a backing layer over the first subcell; and
etching the release layer to separate the solar cell from the InP substrate.

21. The method of claim 20, wherein forming the first subcell over the release layer comprises forming a layer lattice-matched to the InP substrate.

22. The method of claim 20, wherein forming the first subcell over the release layer comprises at least one of forming an InGaAs base layer, forming an InP base layer, forming an InAlGaAs base layer, or forming an InGaAsP base layer.

23. The method of claim 20, further comprising forming a second subcell over the first subcell, wherein the backing layer is formed over the second subcell.

24. The method of claim 23,
wherein forming the first subcell comprises forming an InP base layer; and
wherein forming the second subcell comprises forming an InGaAs base layer.

25. The method of claim 23,
wherein forming the first subcell comprises forming at least one of an InAlAs base layer, an InAlGaAs base layer, or an InGaAsP base layer; and
wherein forming the second subcell comprises forming at least one of an InAlGaAs base layer or an InGaAsP base layer.

26. The method of claim 23, further comprising forming a first tunnel diode between the first subcell and the second subcell.

27. The method of claim 23, wherein forming a first tunnel diode between the first subcell and the second subcell comprises one or both of forming a heavily-doped GaAsSb layer and forming a heavily-doped InP layer.

28. The method of claim 23,
wherein the first subcell has a bandgap in the range of 1.35 eV-1.45 eV; and
wherein the second subcell has a bandgap in the range of 0.6 eV-0.8 eV.

29. The method of claim 23, further comprising forming a third subcell over the second subcell, wherein the backing layer is formed over the third subcell.

30. The method of claim 29,
wherein forming the first subcell comprises forming an InAlAsSb base layer;
wherein forming the second subcell comprises forming at least one of an InAlGaAs base layer or an InGaAsP base layer; and
wherein forming the third subcell comprises forming at least one of an InGaAs base layer, an InAlGaAs base layer or an InGaAsP base layer.

31. The method of claim 29,
wherein forming the first subcell comprises forming an InAlAs base layer;
wherein forming the second subcell comprises forming at least one of an InAlGaAs base layer or an InGaAsP base layer; and
wherein forming the third subcell comprises forming at least one of an InGaAs base layer, an InAlGaAs base layer or an InGaAsP base layer.

32. The method of claim 29, further comprising forming a fourth subcell over the release layer, wherein the fourth subcell is formed before formation of the first subcell.

33. The method of claim 32, wherein a base material of the fourth subcell and a base material of the first subcell is InAlAs or InAlAsSb.

34. The method of claim 29, further comprising:
forming a first tunnel diode between the first subcell and the second subcell; and
forming a second tunnel diode between the second subcell and the third subcell.

35. The method of claim 29,
wherein the first subcell has a bandgap within a range of 1.46 eV to 2.2 eV;
wherein the second subcell has a bandgap within a range of 0.75 eV to 1.5 eV; and
wherein the third subcell has a bandgap within a range of 0.6 eV to 0.8 eV.

36. The method of claim 20, wherein forming the release layer comprises forming at least one of an AlAsSb layer, an AlPSb layer, or a pseudomorphic AlAs layer.

37. The method of claim 20, wherein the formed backing layer is under tensile stress during removal of the release layer.

38. The method of claim 20, further comprising forming a window layer over the release layer, the window layer formed before forming a base layer of the first subcell.

39. The method of claim 20, further comprising reusing the InP substrate to fabricate a second InP-based solar cell free of a substrate.

40. The method of claim 20, wherein etching the release layer to separate the solar cell from the substrate also separates a plurality of other solar cells from the substrate.

41. The method of claim 20, wherein the substrate is a wafer having a diameter within a range of 95 mm to 155 mm.

42.-63. (canceled)

64. A method for fabricating an InP-based solar cell free of a substrate, the method comprising:
forming a compositionally-graded plurality of metamorphic buffer layers on a GaAs substrate;
epitaxially forming a release layer over the compositionally-graded plurality of metamorphic buffer layers;
epitaxially forming a window layer over the release layer;
epitaxially forming a first subcell over the window layer;
forming a backing layer over the first subcell; and
etching the release layer to separate the solar cell from the compositionally-graded plurality of metamorphic buffer layers and the GaAs substrate.

65. The method of claim 64, wherein the compositionally-graded plurality of metamorphic buffer layers includes at least fifteen buffer layers.

66. The method of claim 64, wherein the compositionally-graded plurality of metamorphic buffer layers includes at least twenty buffer layers.

67. The method of claim 64, wherein forming the first subcell over the release layer comprises at least one of forming an InGaAs base layer, forming an InP base layer, forming an InAlGaAs base layer, or forming an InGaAsP base layer.

68. The method of claim 64, further comprising forming a second subcell over the first subcell, wherein the backing layer is formed over the second subcell.

69. The method of claim 68,
wherein forming the first subcell comprises forming an InP base layer; and
wherein forming the second subcell comprises forming an InGaAs base layer.

70. The method of claim 68,
wherein forming the first subcell comprises forming at least one of an InAlAs base layer, an InAlGaAs base layer, or an InGaAsP base layer; and
wherein forming the second subcell comprises forming at least one of an InAlGaAs base layer or an InGaAsP base layer.

71. The method of claim 68, further comprising forming a first tunnel diode between the first subcell and the second subcell.

72. The method of claim 68, wherein forming a first tunnel diode between the first subcell and the second subcell comprises one or both of forming a heavily-doped GaAsSb layer and forming a heavily-doped InP layer.

73. The method of claim 64, wherein forming the release layer comprises forming at least one of an AlAsSb layer, an AlPSb layer, or a pseudomorphic AlAs layer.

74. The method of claim 64, wherein the formed backing layer is under tensile stress during removal of the release layer.

75. The method of claim 64, further comprising forming a window layer over the release layer, the window layer formed before forming a base layer of the first subcell.

76. The method of claim 64, further comprising reusing the GaAs substrate to fabricate a second InP-based solar cell free of a substrate.

77. The method of claim 64, wherein etching the release layer to separate the solar cell from the compositionally-graded plurality of metamorphic buffer layers and the GaAs substrate also separates a plurality of other solar cells from the substrate.

78. The method of claim 64, wherein the substrate is a GaAs wafer having a diameter within a range of 95 mm to 155 mm.

79.-88. (canceled)
